(19) United States
(12) Patent Application Publication
(10) Pub. No.: US 2010/0006334 A1
(43) Pub. Date: Jan. 14, 2010

(54) PRINTED WIRING BOARD AND METHOD FOR MANUFACTURING THE SAME

(75) Inventors: Yoshinori TAKENAKA, Ibi-gun (JP); Takeshi NAKAMURA, Ibi-gun (JP); Takamitsu HATTORI, Ibi-gun (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: IBIDEN CO., LTD, Ogaki-shi (JP)

(21) Appl. No.: 12/476,276

(22) Filed: Jun. 2, 2009

Related U.S. Application Data
(60) Provisional application No. 61/078,564, filed on Jul. 7, 2008.

(51) Int. Cl. H05K 1/14; H05K 3/10

(52) U.S. Cl. 174/262; 29/846; 29/874

(57) ABSTRACT

A printed wiring board including an insulative material, a first conductive circuit formed on the insulative material, a resin insulation layer including a first insulation layer formed on the insulative material and on the first conductive circuit and which insulates between lines of the first conductive circuit, the first insulation layer including inorganic particles having a first average diameter, and a second insulation layer formed on the first insulation layer and including a recessed portion and an opening portion, the second insulation layer including inorganic particles having a second average diameter smaller than the first average diameter, a second conductive circuit formed in the recessed portion, and a via conductor formed in the opening portion and which connects the first conductive circuit to the second conductive circuit.

### CROSS-REFERENCE TO RELATED APPLICATIONS

The present application claims the benefits of priority to U.S. Application No. 61/078,564, filed Jul. 7, 2008. The contents of that application are incorporated herein by reference in their entirety.

### BACKGROUND OF THE INVENTION

1. Field of the Invention

The present invention is related to a printed wiring board and its manufacturing method, in which insulation between wiring lines is sufficiently ensured while sufficient flatness is achieved even when wiring density is high.

2. Discussion of the Background

In recent years, electronic devices have become highly functional, while demand for compact and thinner types has been increasing. Accordingly, electronic components such as IC chips, LSI or the like are rapidly becoming densely integrated. Thus, further progress in wiring density is required in printed wiring boards in which such electronic components are to be loaded.

### SUMMARY OF EMBODIMENTS OF THE INVENTION

A printed wiring board including an insulative material, a first conductive circuit formed on the insulative material, a resin insulation layer including a first insulation layer formed on the insulative material and on the first conductive circuit and which insulates between lines of the first conductive circuit, the first insulation layer including inorganic particles having a first average diameter, and a second insulation layer formed on the first insulation layer and including a recessed portion and an opening portion, the second insulation layer including inorganic particles having a second average diameter smaller than the first average diameter, a second conductive circuit formed in the recessed portion, and a via conductor formed in the opening portion and which connects the first conductive circuit to the second conductive circuit.

A method for manufacturing a printed wiring board including forming a first conductive circuit on a surface of an insulative material, forming, on the insulative material and on the first conductive circuit, a resin insulation layer having a first insulation layer that includes first inorganic particles, and a second insulation layer that is formed on the first insulation layer and includes second inorganic particles whose average diameter is smaller than that of the first inorganic particles, forming an opening portion for a via conductor that penetrates the resin insulation layer, and also forming a recessed portion for a second conductive circuit in the second insulation layer, forming a second conductive circuit in the recessed portion, and forming a via conductor in the opening portion that connects the first conductive circuit and the second conductive circuit.

A printed wiring board including an insulative material, a first conductive circuit formed on the insulative material, a resin insulation layer having a first insulation layer that is formed on the insulative material and on the first conductive circuit and insulates between lines of the first conductive circuit, a second insulation layer that is formed on the first insulation layer and has a recessed portion for a second conductive circuit, and an opening portion for a via conductor, a second conductive circuit formed in the recessed portion, and a via conductor that is formed in the opening portion and connects the first conductive circuit and the second conductive circuit, wherein the first insulation layer includes first inorganic particles, and the second insulation layer is essentially made only of resin.

A method for manufacturing a printed wiring board including forming a first conductive circuit on a surface of an insulative material, forming, on the insulative material and on the first conductive circuit, a resin insulation layer having a first insulation layer that includes first inorganic particles, and a second insulation layer that is formed on the first insulation layer and is essentially made only of resin, forming an opening portion for a via conductor that penetrates the resin insulation layer, and also to a form a recessed portion for a second conductive circuit in the second insulation layer, forming a second conductive circuit in the recessed portion, and forming a via conductor in the opening portion that connects the first conductive circuit and the second conductive circuit.

A printed wiring board including at least one resin insulation layer in which a first recessed portion is formed on a first-surface side and a second recessed portion is formed on a second-surface side, a component-mounting pad formed in the first recessed portion, a conductive circuit formed in the second recessed portion, and a via conductor that carries out interlayer conductivity between the component-mounting pad and the conductive circuit, wherein the at least one resin insulation layer includes a first insulation layer to insulate between the component-mounting pads, a second insulation layer to insulate between lines of the conductive circuit, and a via-conductor opening portion in which to form a via conductor, wherein the first insulation layer includes first inorganic particles, and the second insulation layer includes second inorganic particles whose particle diameters are smaller than those of the first inorganic particles.

A method for manufacturing a printed wiring board including forming a component-mounting pad on a first surface of a support member, forming, on the support member and on the component-mounting pad, a resin insulation layer having a first insulation layer that includes first inorganic particles, and a second insulation layer that is formed on the first insulation layer and includes second inorganic particles whose average diameter is smaller than that of the first inorganic particles, forming an opening for a via conductor that penetrates the first insulation layer and the second insulation layer, and also forming a recessed portion for a second conductive circuit in the second insulation layer, forming a second conductive circuit in the recessed portion, and forming in the opening portion a via conductor to connect the first conductive layer and the second conductive circuit.

A printed wiring board including at least one resin insulation layer in which a first recessed portion is formed on a first surface and a second recessed portion is formed on a second surface, a component-mounting pad formed in the first recessed portion, a conductive circuit formed in the second recessed portion, and a via conductor that carries out interlayer conductivity between the component-mounting pad and the conductive circuit, wherein the at least one resin insulation layer includes a first insulation layer to insulate between the component-mounting pads, a second insulation layer to insulate between lines of the conductive circuit, and a via-conductor opening portion in which to form a via conductor, wherein the first insulation layer includes first inorganic particles, and the second insulation layer is essentially made only of resin.

A method for manufacturing a printed wiring board including forming a component-mounting pad on a first surface of a support member, forming, on the support member and on the component-mounting pad, a resin insulation layer having a first insulation layer that includes first inorganic particles, and a second insulation layer that is formed on the first insulation layer and is essentially made only of resin, forming an opening portion for a via conductor that penetrates the first insulation layer and the second insulation layer, and also forming a recessed portion for a conductive circuit in the second insulation layer, forming a second conductive circuit in the recessed portion, and forming a via conductor in the opening portion to connect the component-mounting pad and the conductive circuit.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically showing a structure of a printed wiring board according to the example First Embodiment of the present invention;

FIG. 2A is a process view (1) showing a step for manufacturing a printed wiring board according to an example First Embodiment;

FIG. 2B is a process view (2) showing a step for manufacturing a printed wiring board according to the example First Embodiment;

FIG. 2C is a process view (3) showing a step for manufacturing a printed wiring board according to the example First Embodiment;

FIG. 2D is a process view (4) showing a step for manufacturing a printed wiring board according to the example First Embodiment;

FIG. 2E is a process view (5) showing a step for manufacturing a printed wiring board according to the example First Embodiment; and

FIG. 2F is a process view (6) showing a step for manufacturing a printed wiring board according to the example First Embodiment.

FIG. 3A is a process view (7) showing a step, continuing from FIG. 2F, for manufacturing a printed wiring board according to the example First Embodiment;

FIG. 3B is a process view (8) showing a step for manufacturing a printed wiring board according to the example First Embodiment; and

FIG. 3C is a process view (9) showing a step for manufacturing a printed wiring board according to the example First Embodiment.

FIG. 4A is a process view (10) showing a step, continuing from FIG. 3C, for manufacturing a printed wiring board according to the example First Embodiment; and

FIG. 4B is a partially magnified view of FIG. 4A.

FIG. 5A is a process view (11) showing a step, continuing from FIG. 4B, for manufacturing a printed wiring board according to the example First Embodiment;

FIG. 5B is a process view (12) showing a step for manufacturing a printed wiring board according to the example First Embodiment; and

FIG. 5C is a process view (13) showing a step for manufacturing a printed wiring board according to the example First Embodiment.

FIG. 6A is a process view (14) showing a step, continuing from FIG. 5C, for manufacturing a printed wiring board according to the example First Embodiment;

FIG. 6B is a process view (15) showing a step for manufacturing a printed wiring board according to the example First Embodiment; and

FIG. 6C is a process view (16) showing a step for manufacturing a printed wiring board according to the example First Embodiment.

FIG. 7A is a process view (17) showing a step, continuing from FIG. 6C, for manufacturing a printed wiring board according to the example First Embodiment; and

FIG. 7B is a cross-sectional view showing a structure of a printed wiring board according to the example First Embodiment.

FIG. 8 is a cross-sectional view showing a structure of a printed wiring board according to an example Second Embodiment of the present invention.

FIG. 9A is a process view (1) showing a step for manufacturing a printed wiring board according to an example Second Embodiment;

FIG. 9B is a process view (2) showing a step for manufacturing a printed wiring board according to an example Second Embodiment;

FIG. 9C is a process view (3) showing a step for manufacturing a printed wiring board according to an example Second Embodiment;

FIG. 9D is a process view (4) showing a step for manufacturing a printed wiring board according to an example Second Embodiment; and

FIG. 9E is a partially magnified view of FIG. 9D.

FIG. 10A is a process view (5) showing a step, continuing from FIG. 9D, for manufacturing a printed wiring board according to an example Second Embodiment; and

FIG. 10B is a process view (6) showing a step for manufacturing a printed wiring board according to an example Second Embodiment.

FIG. 11A is a process view (7) showing a step, continuing from FIG. 10B, for manufacturing a printed wiring board according to an example Second Embodiment; and

FIG. 11B is a process view (8) showing a step for manufacturing a printed wiring board according to an example Second Embodiment.

FIG. 12 is a cross-sectional view schematically showing a structure of a printed wiring board according to the example Third Embodiment of the present invention;

FIG. 13A is a process view (1) showing a step for manufacturing a printed wiring board according to the example Third Embodiment;

FIG. 13B is a process view (2) showing a step for manufacturing a printed wiring board according to the example Third Embodiment;

FIG. 13C is a process view (3) showing a step for manufacturing a printed wiring board according to the example Third Embodiment; and

FIG. 13D is a process view (4) showing a step for manufacturing a printed wiring board according to the example Third Embodiment.

FIG. 14A is a process view (5) showing a step, continuing from FIG. 13D, for manufacturing a printed wiring board according to the example Third Embodiment;

FIG. 14B is a partially magnified view of FIG. 14A;

FIG. 14C is a process view (6) showing a step for manufacturing a printed wiring board according to the example Third Embodiment;

FIG. 14D is a process view (7) showing a step for manufacturing a printed wiring board according to the example Third Embodiment;

FIG. 14E is a process view (8) showing a step for manufacturing a printed wiring board according to the example Third Embodiment; and

FIG. 14F is a process view (9) showing a step for manufacturing a printed wiring board according to the example Third Embodiment.

FIG. 15A is a process view (10) showing a step, continuing from FIG. 14F, for manufacturing a printed wiring board according to the example Third Embodiment;

FIG. 15B is a process view (11) showing a step for manufacturing a printed wiring board according to the example Third Embodiment;

FIG. 15C is a process view (12) showing a step for manufacturing a printed wiring board according to the example Third Embodiment; and

FIG. 15D is a process view (13) showing a step for manufacturing a printed wiring board according to the example Third Embodiment.

FIG. 16A is a process view (14) showing a step, continuing from FIG. 15D, for manufacturing a printed wiring board according to the example Third Embodiment;

FIG. 16B is a process view (15) showing a step for manufacturing a printed wiring board according to the example Third Embodiment;

FIG. 16C is a process view (16) showing a step for manufacturing a printed wiring board according to the example Third Embodiment; and

FIG. 16D is a process view (17) showing a step for manufacturing a printed wiring board according to the example Third Embodiment.

FIG. 17 is a cross-sectional view showing a structure of a printed wiring board according to an example Fourth Embodiment;

FIG. 18A is a process view (1) showing a step for manufacturing a printed wiring board according to the example Fourth Embodiment; and

FIG. 18B is a partially magnified view of FIG. 18A.

FIG. 19A is a cross-sectional view showing a conductive circuit and resin layer of a printed wiring board in a Comparative Example; and

FIG. 19B is a photograph taken by an electron microscope showing a magnified cross-sectional view of the printed wiring board in the Comparative Example of FIG. 19A.

FIG. 20A is a photograph taken by an electron microscope showing a magnified cross-sectional view of a conductive circuit and a resin layer of a printed wiring board in Example (1); and

FIG. 20B is a photograph taken by an electron microscope showing a magnified cross-sectional view of a conductive circuit and a resin layer of a printed wiring board in Example (1).

### DETAILED DESCRIPTION OF THE EMBODIMENTS

The embodiments will now be described with reference to the accompanying drawings, wherein like reference numerals may designate corresponding or identical elements throughout the various drawings.

As noted above, further progress in wiring density is required in printed wiring boards. When wiring density increases, a width of a wiring line and a width of a space between wiring lines (expressed as wiring line/space or L/S) decreases as a matter of course.

Here, if the wiring line/space (L/S) decreases, an aspect ratio of the wiring (measured as the height divided by the width of a cross section of the wiring) increases. When wiring having a high aspect ratio is formed on a resin insulation layer surface, its adhesiveness with the resin insulation layer may possibly be lowered. To deal with an issue such as sufficient adhesiveness between the wiring and a resin insulation layer, for example, technology disclosed in Japanese Patent Publication 3629375 (hereinafter referred to as “conventional art”) is suggested. The content of this publication is incorporated herein by reference in its entirety. The above conventional art discloses embedding wiring in a resin insulation layer, which is excellent in securing sufficient adhesiveness of the wiring to the resin insulation layer.

However, the present inventors have recognized that when embedding wiring in a resin insulation layer, it is important to form the resin insulation layer flat in order to secure interlayer insulation. To ensure the flatness of a resin insulation layer, liquidity of such a resin insulation layer is important during the manufacturing process. Also, resin insulation layers forming a printed wiring board usually contain inorganic particles of oxides, such as silica, alumina or zirconia, to lower their thermal expansion coefficients. In the figures of the above conventional art publication, when forming a resin insulation layer on a core substrate, if the liquidity of the resin insulation layer is low due to inorganic particles, voids may occur, for example, between the resin insulation layer and a wiring pattern in spaces between adjacent lines of the wiring pattern. Then, such voids may cause hollows on a surface of the resin insulation layer.

Meanwhile, as the wiring line/space (L/S) decreases, ensuring insulation between wiring lines is also an important issue. The inventors recognized in the above conventional art, when wiring is embedded in an interlayer insulation layer, insulation between wiring lines is affected by inorganic particles contained in the resin insulation layer. For example, the inventors discovered that voids in the resin insulating layer may be filled with conductor material, thereby reducing insulation between wiring. The present invention was carried out in consideration of such situations.

Namely, a first aspect of the present invention is related to a first printed wiring board characterized by the following: an insulative material; a first conductive circuit formed on the insulative material; a resin insulation layer having a first insulation layer that is formed on the insulative material and on the first conductive circuit and insulates between lines of the first conductive circuit, a second insulation layer that is formed on the first insulation layer and has a recessed portion for a second conductive circuit, and an opening portion for a via conductor; a second conductive circuit formed in the recessed portion; and a via conductor that is formed in the opening portion and connects the first conductive circuit and the second conductive circuit. Also, the first insulation layer contains first inorganic particles, and the second insulation layer contains second inorganic particles whose particle diameters are smaller than those of the first inorganic particles.

Here, it is preferred that the surface of the second conductive circuit formed in the recessed portion be positioned substantially on the same level as the surface of the resin insulation layer. Also, the thickness of the first insulation layer is preferred to be made greater than the thickness of the first conductive circuit; and the thickness of the second insulation layer is preferred to be made greater than the thickness of the second conductive circuit.

A second particle contained in the second insulation layer are preferred to make up 10-70 weight percent of the total weight of the resin forming the second insulation layer. The first inorganic particles and second inorganic particles are preferred to be at least one or more kinds of compounds selected from among groups of inorganic oxides, carbides, inorganic nitrides, mineral salts and silicates. Furthermore, the inorganic particles are preferred to be coated with a surface reforming agent.

The second aspect of the present invention is related to a method for manufacturing a first printed wiring board characterized by the following: a step to form a first conductive circuit on a surface of an insulative material; on the insulative material and on the first conductive circuit, a step to form a resin insulation layer having a first insulation layer that contains first inorganic particles, and a second insulation layer that is formed on the first insulation layer and contains second inorganic particles whose average diameter is smaller than that of the first inorganic particles; a step to form an opening portion for a via conductor that penetrates the resin insulation layer, and also to form a recessed portion for a second conductive circuit in the second insulation layer; a step to form a second conductive circuit in the recessed portion; and a step to form a via conductor in the opening portion that connects the first conductive circuit and the second conductive circuit.

Here, it is preferred to form the recessed portion in such a way that the depth of the recessed portion is shallower than the thickness of the second insulation layer. Also, the opening portion and the recessed portion are preferred to be formed by a laser; and it is preferred that the recessed portion be formed by an exima laser or a UV laser, and the opening portion be formed by a carbon dioxide gas laser. Furthermore, it is preferred to form the second conductive circuit in such a way that the surface of the resin insulation layer is set on substantially the same level as the surface of the second conductive circuit.

A third aspect of the present invention is related to a second printed wiring board characterized by the following: an insulative material; a first conductive circuit formed on the insulative material; a resin insulation layer having a first insulation layer that is formed on the insulative material and on the first conductive circuit and insulates between lines of the first conductive circuit, a second insulation layer that is formed on the first insulation layer and has a recessed portion for a second conductive circuit, and an opening portion for a via conductor; a second conductive circuit formed in the recessed portion; and a via conductor that is formed in the opening portion and connects the first conductive circuit and the second conductive circuit. Also, the first insulation layer contains first inorganic particles, and the second insulation layer is essentially made only of resin.

A fourth aspect of the present invention is related to a method for manufacturing the second printed wiring board characterized by the following: a step to form a first conductive circuit on a surface of an insulative material; a step to form, on the insulative material and on the first conductive circuit, a resin insulation layer having a first insulation layer that contains first inorganic particles, and a second insulation layer that is formed on the first insulation layer and is essentially made only of resin; a step to form an opening portion for a via conductor that penetrates the resin insulation layer, and also to form a recessed portion for a second conductive circuit in the second insulation layer; a step to form a second conductive circuit in the recessed portion; and a step to form a via conductor in the opening portion that connects the first conductive circuit and the second conductive circuit.

A fifth aspect of the present invention is related to a third printed wiring board characterized by the following: at least one resin insulation layer in which a first recessed portion is formed on a first-surface side and a second recessed portion is formed on a second-surface side; a component-mounting pad formed in the first recessed portion; a conductive circuit formed in the second recessed portion; and a via conductor that carries out interlayer conductivity between the component-mounting pad and the conductive circuit. Also, the resin insulation layer has a first insulation layer to insulate between the component-mounting pads, a second insulation layer to insulate between lines of the conductive circuit, and a via-conductor opening portion in which to form a via conductor. Furthermore, the first insulation layer contains first inorganic particles, and the second insulation layer contains second inorganic particles whose particle diameters are smaller than those of the first inorganic particles.

A sixth aspect of the present invention is related to a method for manufacturing a third printed wiring board characterized by the following: a step to form a component-mounting pad on a first surface of a support member; on the support member and on the component-mounting pad, a step to form a resin insulation layer having a first insulation layer that contains first inorganic particles, and a second insulation layer that is formed on the first insulation layer and contains second inorganic particles whose average diameter is smaller than that of the first inorganic particles; a step to form an opening for a via conductor that penetrates the first insulation layer and the second insulation layer, and also to form a recessed portion for a second conductive circuit in the second insulation layer; a conductive-circuit forming step to form a second conductive circuit in the recessed portion; and a via-conductor forming step to form in the opening portion a via conductor to connect the first conductive layer and the second conductive circuit.

A seventh aspect of the present invention is related to a fourth printed wiring board characterized by the following: at least one resin insulation layer in which a first recessed portion is formed on a first surface and a second recessed portion is formed on a second surface; a component-mounting pad formed in the first recessed portion; a conductive circuit formed in the second recessed portion; and a via conductor that carries out interlayer conductivity between the component-mounting pad and the conductive circuit. Also, the resin insulation layer has a first insulation layer to insulate between the component-mounting pads, a second insulation layer to insulate between lines of the conductive circuit, and a via-conductor opening portion in which to form a via conductor. Furthermore, the first insulation layer contains first inorganic particles, and the second insulation layer is essentially made only of resin.

An eighth aspect of the present invention is related to a method for manufacturing a fourth printed wiring board characterized by the following: a step to form a component-mounting pad on a first surface of a support member; a step to form, on the support member and on the component-mounting pad, a resin insulation layer having a first insulation layer that contains first inorganic particles, and a second insulation layer that is formed on the first insulation layer and is essentially made only of resin; a step to form an opening for a via conductor that penetrates the first insulation layer and the second insulation layer, and also to form a recessed portion for a conductive circuit in the second insulation layer; a step to form a second conductive circuit in the recessed portion; and a step to form a via conductor in the opening portion to connect the component-mounting pad and the conductive circuit.

By employing such a structure, a printed wiring board with excellent flat features may be manufactured.

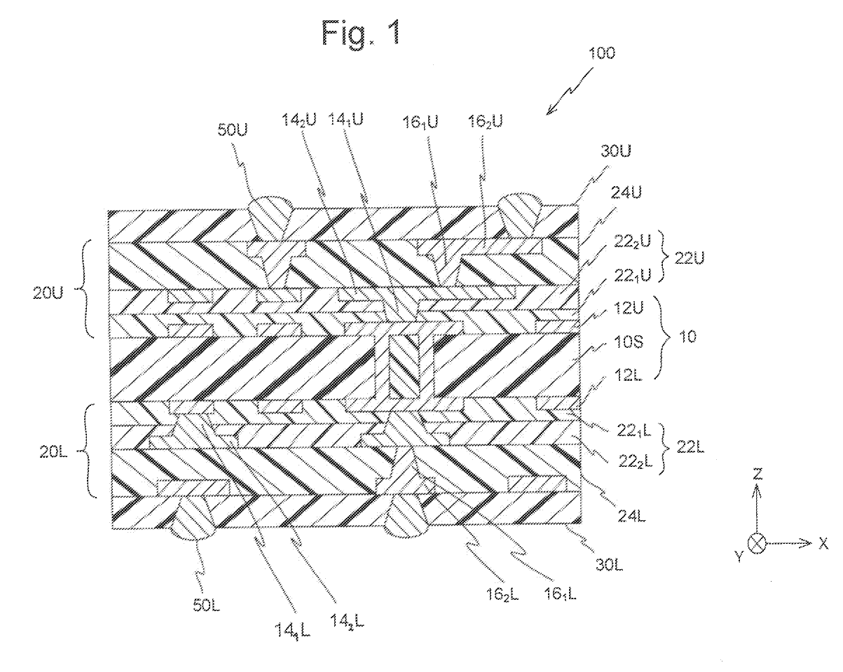

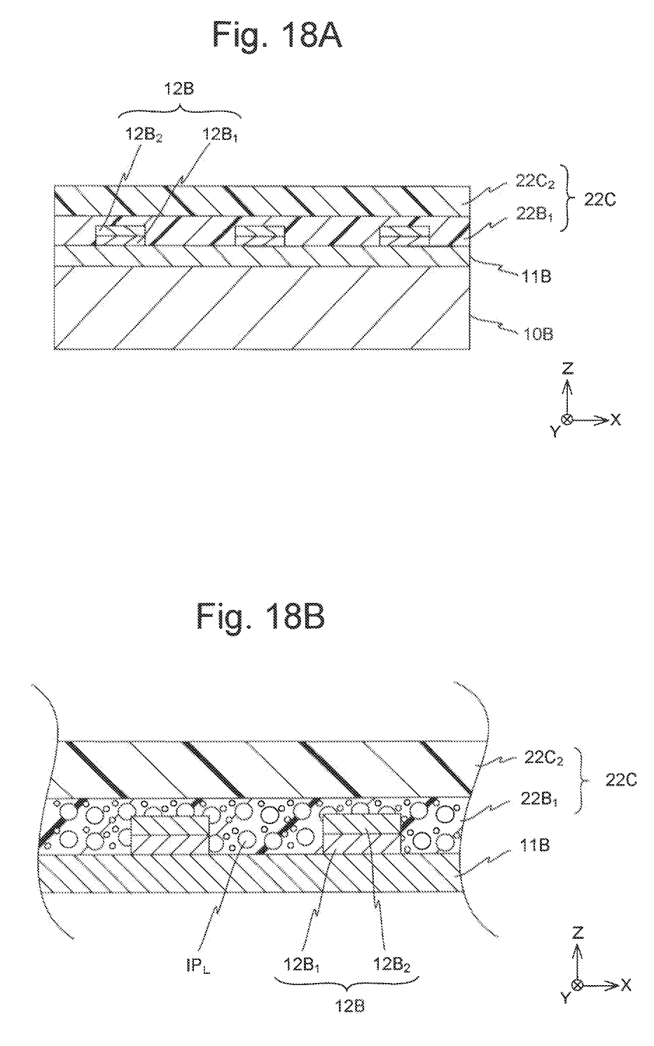

In the following, examples of a printed wiring board of the present invention are described in detail according to the First to Fourth Embodiments by referring to FIGS. 1-20. In the following description and drawings, corresponding reference numbers may have been applied to corresponding or equivalent elements and their redundant descriptions have been omitted.

### First Example Embodiment

First, a description of the example First Embodiment is now provided. FIG. 1 shows a structure of printed wiring board (100) according to the First example Embodiment of the present invention, illustrating the positional relationships of core substrate (10), laminated sections (20U, 20L), solder resists (30U, 30L) and solder members (solder bumps) (50U, 50L), which form printed wiring board (100).

As shown in FIG. 1, printed wiring board (100) has the following: (a) core substrate (10); (b) laminated section (20U) formed on the (+Z) direction side of core substrate (10); (c) solder member (50U) arranged on conductive circuit (16₂U), including a pad portion, which is formed on the (+Z) direction-side surface (first surface) of the outermost layer among the resin insulation layers in laminated section (20U); (d) solder resist (30U) formed on the (+Z) direction-side surface of laminated section (20U); (e) laminated section (20L) formed on the (−Z) direction-side of core substrate (10); (f) solder member (50L) arranged on conductive circuit (16₂L), including a pad portion, which is formed on the (−Z) direction-side surface (second surface) of the outermost layer among the resin insulation layers in laminated section (20L); and (g) solder resist (30L) formed on the (−Z) direction-side surface of laminated section (20L).

Core substrate (10) has the following: (i) insulation member (10S) as an “insulative material”; (ii) conductive circuit (12U) formed on the (+Z) direction-side surface of insulative member (10S); and (iii) conductive circuit (12L) formed on the (−Z) direction-side surface of insulation member (10S).

Laminated section (20U) has the following: (i) resin insulation layer (22U) formed on the (+Z) direction side of core substrate (10); (ii) conductive circuit (14₂U) formed on the (+Z) direction-side surface of resin insulation layer (22U); and (iii) via conductor (14₁U) which electrically connects conductive circuit (12U) and conductive circuit (14₂U).

As shown in FIG. 1, resin insulation layer (22U) is not formed with a single resin layer, but with two resin layers (22₁U, 22₂U) each containing inorganic particles that have different particle diameters. Namely, on the (+Z) direction-side surface of core substrate (10), resin layer (22₁U) (first insulation layer) containing inorganic particles with larger particle diameters is formed; and on the (+Z) direction-side surface of resin layer (22₁U), resin layer (22₂U) (second insulation layer) containing inorganic particles with smaller particle diameters than the inorganic particles contained in (22₁U) is formed.

Furthermore, laminated section (20U) has the following: (iv) resin insulation layer (24U) formed on the (+Z) direction-side surfaces of resin insulation layer (22U) and conductive circuit (14₂U); (v) conductive circuit (16₂U) formed on the (+Z) direction-side surface of resin insulation layer (24U); and (iii) via conductor (16₁U) which electrically connects conductive circuit (14₂U) and conductive circuit (16₂U).

Laminated section (20L) is formed the same as above-described laminated section (20U) except that the direction in which it is laminated is the (−Z) direction. Therefore, to refer to a structural element of laminated section (20L) that corresponds to that of laminated section (20U), an “L” is attached at the end so that it can be distinguished from a structural element of laminated section (20U) with a “U” attached at the end. The configurations of conductive circuits (12U, 14₂U, 16₂U) and the positions where via conductors (14₁U, 16₁U) are formed usually differ from the configurations of conductive circuit (12L, 14₂L, 16₂L) and the positions where via conductors (14₁L, 16₁L) are formed. Also, one or more wiring layers, each of which is made up of a resin insulation layer, a conductive circuit and via conductors, may be arranged between resin insulation layers 22U (22L) and resin insulation layers 24U (24L).

As shown in FIG. 1, according to the First Embodiment, conductive circuits (14₂U, 16₂U) are embedded in resin insulation layers (22U, 24U) in such a way that they are set on substantially the same level as the (+Z) direction-side surfaces (first surfaces) of the resin insulation layers. However, if more wiring layers are further formed, part of such wiring layers may be formed on the (+Z) direction-side surface (first surface) of a resin insulation layer.

Also, according to the First Embodiment, conductive circuits (14₂L, 16₂L) are embedded in resin insulation layers (22L, 24L) in such a way that they are set on substantially the same level as the (−Z) direction-side surfaces of the resin insulation layers. However, if more wiring layers are further formed, part of such wiring layers may be formed on the (−Z) direction-side surface of a resin insulation layer.

When further forming more wiring layers, other than the above-described method for forming embedded wiring (the LPP method), either a semi-additive method or a subtractive method may also be used; needless to say, a combination of such methods may also be used.

Next, manufacturing printed wiring board (100) of the First Embodiment is described according to an example that uses a support member having a conductive layer on both of its surfaces.

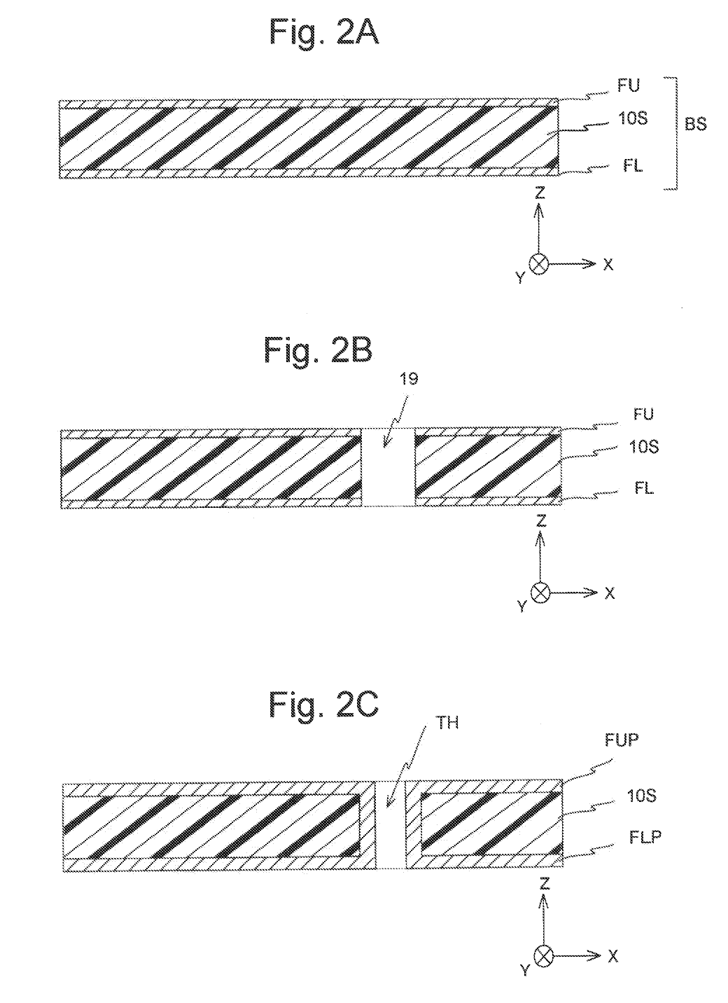

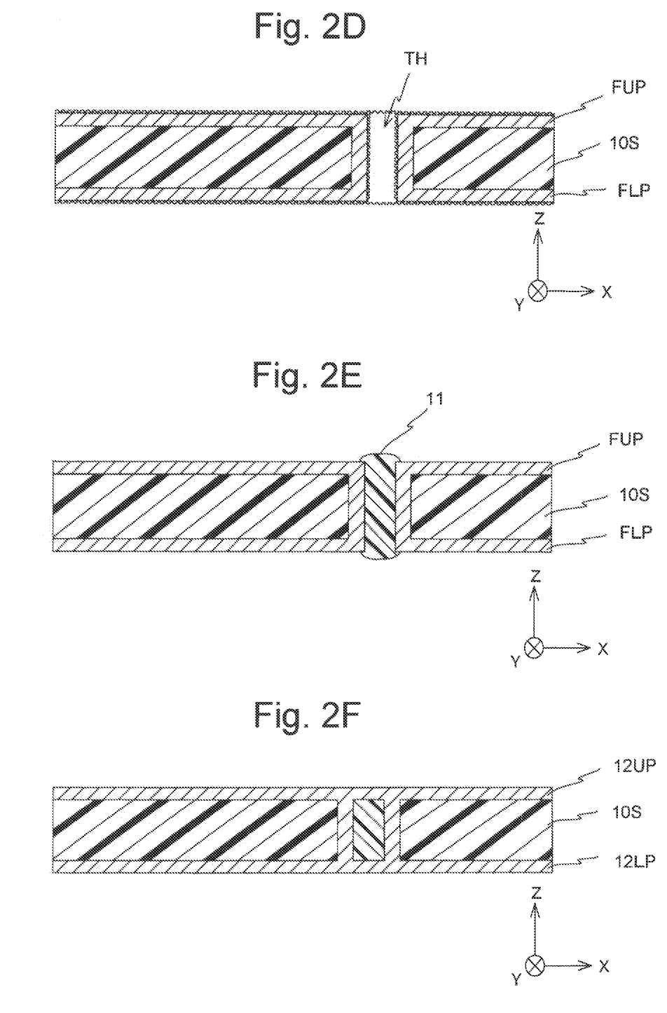

When manufacturing printed wiring board (100), support member (BS) is first prepared (see FIG. 2A). Support member (BS) is made up of insulation member (10S) and conductive layers (FU, FL) formed on both surfaces of insulation member (10S). Conductive layers (FU, FL) are metal foils with a thickness in the range of approximately a few μm to a couple of dozen μm. As for insulation member (10S), for example, glass laminate impregnated with bismaleimide-triazine resin, glass laminate impregnated with polyphenylene ether resin, glass laminate impregnated with polyimide resin, copper-clad laminate with fluorocarbon resin made by thermally pressure-pressing a copper foil with a roughened surface on a fluorocarbon resin substrate such as polytetrafluoroethylene, ceramic laminate or the like may be listed. Also, a commercially available double-sided copper-clad laminate or single-sided copper clad laminate may be used. As for such commercially available products, for example, MCL-E679 FGR, made by Hitachi Chemical Co., Ltd., or the like is listed. Also, a metal plate may be used as support member (BS).

First, in insulation member (10S), through-hole (19) for electrical continuity is opened using a drill (see FIG. 2B). The diameter of such a through-hole is preferred to be in the approximate range of 0.15-0.30 μm, more preferably in the approximate range of 0.18-0.25 μm.

Next, a desmear treatment is conducted on the inner wall of through-hole (19) formed as such, then electroless plating and electrolytic plating are performed in that order to form an electrolytic plated film on an electroless plated film. For example, using a plating bath shown in Table (1) below, and by immersing the support member under conditions of bath temperature at 60-80° C. for 15-45 minutes, a thin electroless plated film may be formed.

TABLE 1
electroless plating bath composition (1)

| name of compound | amount |
|---|---|
| EDTA | approx. 150 g/L |
| copper sulfate | approx. 20 g/L |
| HCHO | approx. 30 ml/L |
| NaOH | approx. 40 g/L |
| α,α'-bipyridyl | approx. 80 mg/L |
| PEG | approx. 0.1 g/L |

Next, using, for example, a bath shown below in Table (2), electrolytic plating is performed under conditions of electric current at 0.5-2 A/dm², power-on time for 15-45 minutes and bath temperature at 20-40° C. to form a thick electrolytic plated film (see FIG. 2C). As a result, conductive films (FUP, FLP) are formed.

In FIG. 2C, conductive films (FUP, FLP) are each illustrated as one layer.

TABLE 2
electrolytic plating bath composition (1)

| name of compound | amount |
|---|---|
| sulfuric acid | approx. 180 g/L |
| copper sulfate | approx. 80 g/L |
| additive | approx. 1 ml/L |

As for an additive to be used in such an electrolytic plating bath, for example, Cupracid GL (made by Atotec Japan) or the like may be listed.

Insulation member (10S), where conductive layers made of an electroless plated film and an electrolytic plated film are formed as above, is washed with water and dried. Then, a roughening treatment is conducted to enhance adhesiveness between the resin to be filled in through-hole (19) and the plated film formed on the inner wall of the through-hole (see FIG. 2D). For example, a roughening treatment may be conducted through a black oxide treatment using an oxidation bath composition and a reduction bath composition shown below in Table (3)

TABLE 3

| oxidation bath (black oxide bath) | reduction bath |
|---|---|
| NaOH (approx. 10 g/L) | NaOH (approx. 10 g/L) |
| NaClO₂ (approx. 40 g/L) | Na₄ or NaBH₄ (approx. 6 g/L) |
| Na₃PO₄ (approx. 6 g/L) | |

Next, metal mask is placed on the (+Z) direction-side surface of the plated film after the black oxide treatment. Then, a filling material made with, for example, silica particles, bisphenol F-type epoxy resin, a leveling agent and a curing agent in the amount of 150-200, 75-125, 1-2 and 5-8 respectively (ratios by weight), is prepared, filled in the through-hole using a squeegee, dried and cured (see FIG. 2E).

Then, metal mask (M) is removed and the filling agent which has spilled from the through-hole and covers the plated films is shaved by polishing to be on substantially the same level as the plated films. Such removal of the filling agent may be conducted by belt-sander polishing, buff polishing or the like.

In the following, desmear treatment is conducted to form a plated layer including the polished surface of filling resin (11). After a plated film is formed by electroless plating, an electrolytic plated film is formed by electrolytic plating. Accordingly, conductive films (12UP, 12LP) are formed (see FIG. 2F).

Electroless plating as part of the step shown in FIG. 2F may be performed using a regular method after applying a catalyst on the surfaces of the support member, where their flatness is ensured as above. For example, a palladium catalyst (made by Atotec Japan) is applied and electroless copper plating is performed to form an electroless plated film with a thickness in the range of 0.1-0.5 μm. Then, by performing electrolytic plating under the above-mentioned conditions, an electrolytic plated film with a thickness in the range of 5-25 i,m may be formed on the electroless plated film. In FIG. 2F, conductive films (12UP, 12LP) are each shown as one layer, other than showing discrete electrolytic and electroless plating layers.

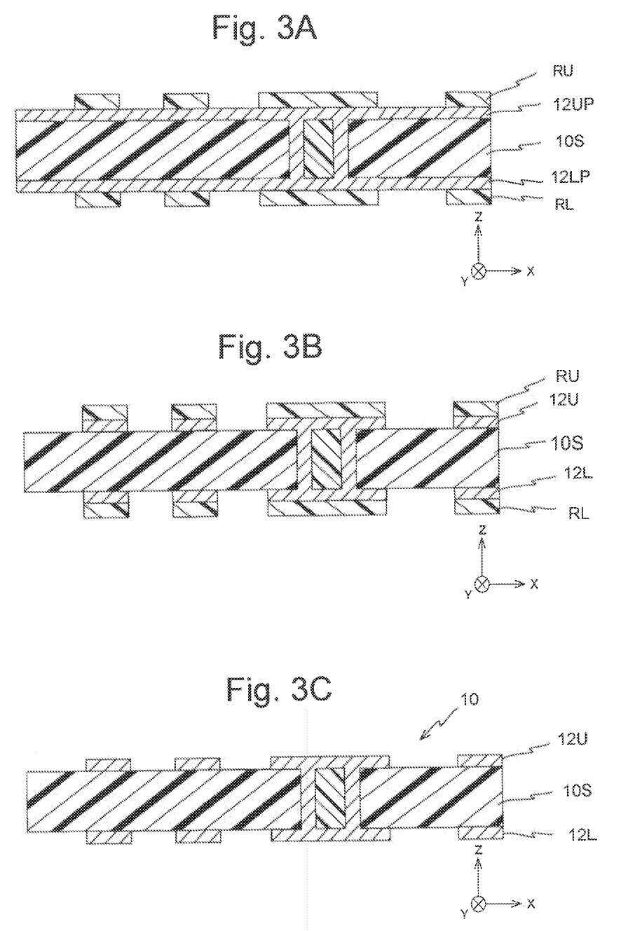

In the following, conductive circuits that cover conductive circuits (12U, 12L) and filling resin (11) are formed at the same time on both surfaces of insulation substrate (10) using a subtractive method (see FIGS. 3A-3C).

Namely, a photosensitive dry film is laminated on a surface of the plated film, and a patterned photomask film is placed on the dry film, which is then exposed to light and developed using a developing solution. Accordingly, etching resists (RU, RL) are formed (see FIG. 3A). A photomask here is preferred to be made of glass. As described above, after a dry film is laminated, a photomask is placed thereon, then the film is exposed to light at, for example, 80-120 mJ/cm², and developed using a 0.5-1.0% sodium carbonate solution. Accordingly, an etching resist may be formed to be approximately 10-20 μm thick (see FIG. 3A).

Next, as shown in FIG. 3B, by etching the area where the etching resist is not formed, a member may be obtained where conductive circuits and through-hole-covering conductive layer portions that cover the filling material are formed. As for an etching solution here, for example, a mixed solution of sulfuric acid and hydrogen peroxide, a persulfate solution of ammonium persulfate, sodium persulfate, potassium persulfate or others, iron (II) chloride solution, copper (II) chloride solution or the like may be listed.

The plated film on the area where the etching resist is not formed is etched away using, for example, the above mixed solution of sulfuric acid and hydrogen peroxide, and the etching resist is removed using a 5% potassium hydroxide solution. As a result, conductive circuits (12U, 12L) and through-hole-covering conductive layers (hereinafter, also referred to simply as “conductive circuits”) which cover filling material are formed (see FIG. 3C). Accordingly, core substrate (10) is manufactured.

The surfaces of conductive circuits (12U, 12L) and the through-hole-covering conductive layers may be roughened. In such a case, for example, an etching solution containing imidazole copper complex may be used; a commercially available etching solution such as MEC Etch Bond (made by Mec Co., Ltd.) or the like may also be used.

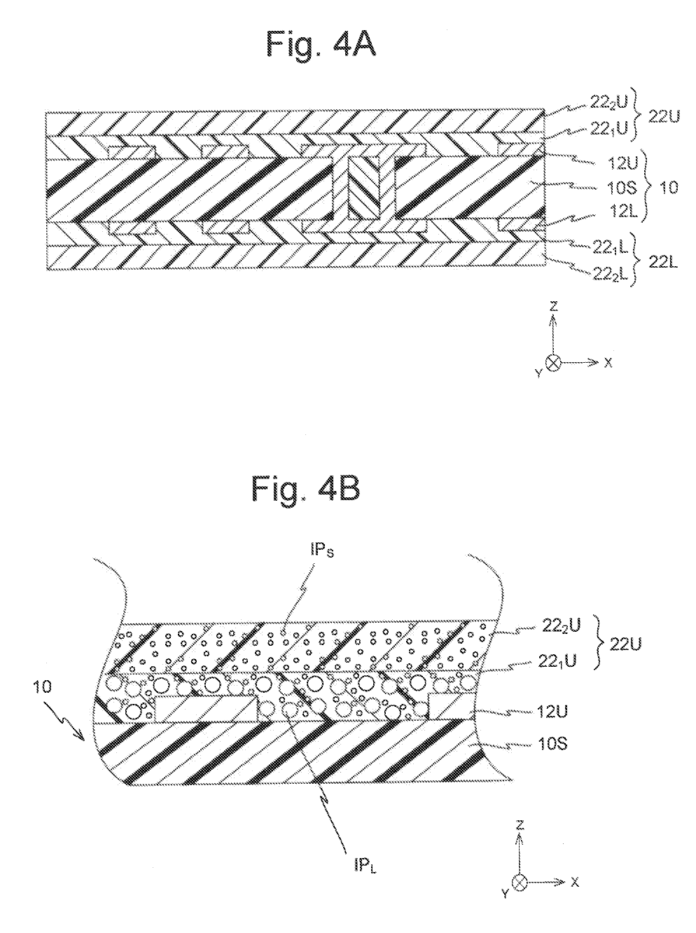

Next, resin insulation layer (22U) is formed to cover each (+Z) direction-side surface of conductive circuit (12U) formed as above and the area of support member (10S) exposed through etching. Resin insulation layer (22U) has first insulation layer (22₁U) which is made of resin containing first inorganic particles (IP_{L}), and second insulation layer (22₂U) which is formed on the (+Z) direction-side surface of first insulation layer (22₁U) and has second inorganic particles (IP_{S}) having a smaller average diameter than that of the first inorganic particles (see FIGS. 4A, 4B)

Also, on each (−Z) direction-side surface of conductive circuit (12L) and areas of support member (10S) exposed through etching, first insulation layer (22₁L) and second insulation layer (22₂L) are also formed the same way as first insulation layer (22₁U) and second insulation layer (22₂U) were formed above. Accordingly, resin insulation layers (22U, 22L) are formed (see FIGS. 4A, 4B)

Resin insulation layer (22U) may be formed by laminating a first insulation layer and a second insulation layer on core substrate (10) in that order; or it may be formed by bonding a first insulation layer and a second insulation layer in advance to make them one sheet, which is then laminated on core substrate (10). Insulation layer (22U) may be formed by laminating under conditions of pressure at approximately 0.5-0.9 MPa, temperature at 80-120° C. and time of 15-45 seconds, then by thermosetting at approximately 160-200° C. for 15-45 minutes.

First inorganic particles contained in first insulation layers 22₁U (22₁L) are preferred to have an average particle diameter of 0.2-3 μm, more preferably an average particle diameter of 0.3-0.7 μm. If the average particle diameter of the first inorganic particles is smaller than 0.2 μm, the liquidity of the resin forming first insulation layers 22₁U (22₁L) decreases, and its performance when filling between lines of conductive circuits 12U (12L) may be lowered. On the other hand, if the average particle diameter of the first inorganic particles exceeds 3 μm, the flatness feature of the surfaces of resin insulation layers 22U (22L) may be lowered, and when conductive circuits 14₂U (14₂L) have especially fine spaces, the thickness of 14₂U (14₂L) may vary widely.

Second inorganic particles contained in second insulation layers 22₂U (22₂L) are preferred to have an average particle diameter of 0.01-0.03 μm, more preferably an average particle diameter of 0.015-0.025 μm. If the average particle diameter of the second inorganic particles is smaller than 0.01 μm, the dispersion feature of the second inorganic particles in the resin insulation layer is lowered, and the thermal expansion coefficients in resin insulation layers 22U (22L) may be difficult to make uniform. On the other hand, if the average particle diameter of the second inorganic particles exceeds 0.03 μm, when the second inorganic particles fall off, substantially uneven configurations may result in recessed portions for conductive circuits 14U₂ (14L₂) formed in second insulation layers 22₂U (22₂L) by a laser as described later. Such is not preferred, since it may lower electrical characteristics under the skin effect.

Also, the first inorganic particles in the resin that forms first insulation layers 22₁U (22₁L) are preferred to make up 10-70 weight percent of the total weight of the resin forming the first insulation layer, more preferably 40-60 weight percent. If the amount of the first inorganic particles is less than 10 weight percent, the thermal expansion coefficient of the resin that forms first resin layers 22₁U (22₁L) increases, and conductive circuits 12U (12L) and first insulation layers 22₁U (22₁L) may come off easily. In addition, the liquidity of the resin that forms first insulation layers 22₁U (22₁L) declines, causing lowered performance in filling between lines of the conductive circuit. As a result, the thickness of the resin insulation layer may vary widely.

On the other hand, if the amount of the first inorganic particles exceeds 70 weight percent, due to the excess amount of the first inorganic particles, first insulation layer (22₁U), which forms resin insulation layer (22U), may easily be prevented from adhering well to conductive circuit (12U). That may cause, for example, the resin insulation layer to be removed from the conductive circuit at their interface during solder reflow. Furthermore, inorganic particles are not pushed away and thus remain at the bottom of later-described via holes, causing decreased interlayer connectivity.

The second inorganic particles in the resin that forms second insulation layers 22₂U (22₂L) are preferred to make up 10-70 weight percent of the total weight of the resin forming the second insulation layer, more preferably 40-60 weight percent. If the amount of the second inorganic particles is less than 10 weight percent, the thermal expansion coefficient of the resin that forms second resin layers 22₂U (22₂L) increases, and conductive circuits 14₂U (14₂L) and second insulation layers 22₂U (22₂L) may come off easily. On the other hand, if the amount of the second inorganic particles exceeds 70 weight percent, an excessive anchor effect may result. Accordingly, it may be difficult to form wiring configurations with excellent electrical characteristics.

The resins that form first insulation layers 22₁U (22₁L) and second insulation layers 22₂U (22₂L) are selected from among thermosetting resin, photosensitive resin, resin with a photosensitive group added to part of thermosetting resin, a resin complex containing such resins as listed here and thermoplastic resin, or the like. The resins that form first insulation layers 22₁U (22₁L) and second insulation layers 22₂U (22₂L) may be the same kind or different kinds. However, considering adhesiveness between the first insulation layer and the second insulation layer, it is preferred to use the same kind of resin.

Also, first insulation layers 22₁U (22₁L) should be made in a line space wide enough to insulate between adjacent lines of the above-described conductive circuits 12U (12L). The space width is preferred to be made greater than the line width of conductive circuits 12U (12L). Specifically, it is preferred to be set at approximately 20-30 μm. In first insulation layers 22₁U (22₁L), portions that are filled between lines of conductive circuits 12U (12L) will insulate between lines of the conductive circuit which are adjacent on the plane surface.

Second insulation layers 22₂U (22₂L) should be made in a line space wide enough so that they can insulate between lines of conductive circuits 14₂U (14₂L); the line space width is preferred to be made greater than the line width of conductive circuit 14₂U (14₂L). Specifically, it is preferred to be set at approximately 10-20 μm. In second insulation layers 22₂U (22₂L), recessed portions for forming a conductive circuit will be formed in a later-described method. The resin between the recessed portions will insulate between lines of the conductive circuit which are adjacent on the plane surface.

As for resin insulation layers (22U, 22L), for example, multiple sheets of interlayer insulation films, prepreg or other semi-cured resin sheets may be used. From a perspective of simplifying the process, it is further preferred to use a sheet made by bonding multiple interlayer insulation films or the like. Also, resin insulation layers may be formed, for example, by screen printing an uncured liquid resin on the above-described metal foil.

Resin insulation layers (22U, 22L) may be formed by separately laminating on a substrate an interlayer insulation film that forms the first insulation layer and an interlayer insulation film that forms the second insulation layer.

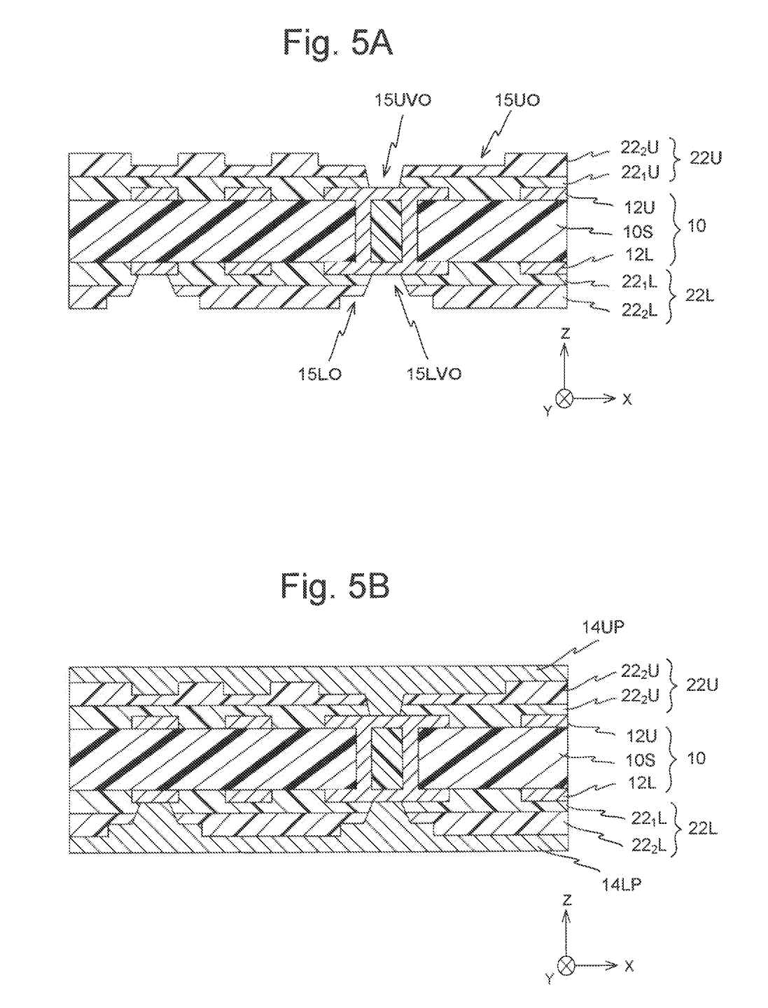

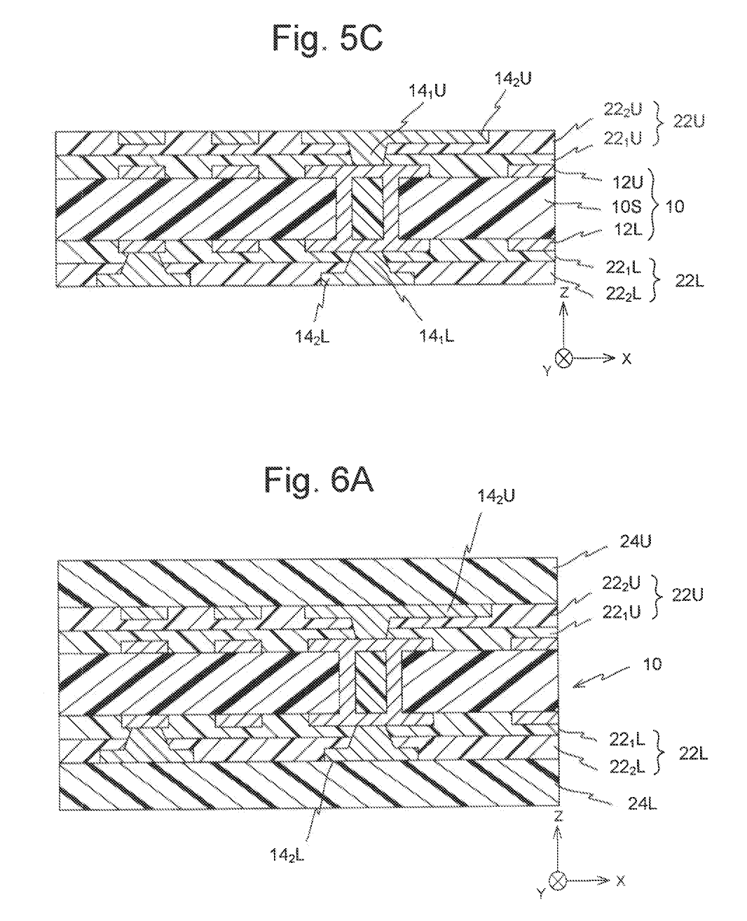

Next, as shown in FIG. 5A, a predetermined number of via-conductor opening portions (15UVO, 15LVO) for interlayer connection are formed. As for lasers to be used for making such opening portions, a carbon dioxide gas laser, exima laser, YAG laser or UV laser or the like may be listed. When forming opening portions using a laser, a protective film such as a PET (polyethylene terephthalate) film or the like may be used.

In the following, as shown in FIG. 5A, first recessed portions (15UO, 15LO) for conductive circuits are formed by conducting the second laser process using a UV laser or an exima laser.

When conducting the second laser process, it is preferred that the resin residue remaining at the bottom of via-conductor opening portions (15UVO, 15LVO) be removed at the same time. In doing so, connection reliability may be enhanced between the later-formed via conductors and the later-formed pads.

Also, after forming conductive-circuit recessed portions (15UO, 15LO) and via-conductor opening portions (15UVO, 15LVO), the member may be immersed in a permanganate solution to roughen the surfaces of resin insulation layers (22₂U, 22₂L).

Next, as shown in FIG. 5B, plated layers (14UP, 14LP) are formed, each of which is made up of an electroless plated film (electroless copper-plated film) and an electrolytic plated film (electrolytic copper-plated film) formed on the electroless plated film in such a way to cover the surfaces of resin insulation layers (22₂U, 22₂L) including via-conductor opening portions (15UVO, 15LVO) and first recessed portions (15UO, 15LO).

Next, plated layers (14UP, 14LP) are polished until the surfaces of resin insulation layers (22₂U, 22₂L) are exposed. Accordingly, via conductors (14₁U) and conductive circuit (14₂U) are formed to be embedded in resin insulation layer (22U), and via conductors (14₁L) and conductive circuit (14₂L) are also formed to be embedded in resin insulation layer (22L) (see FIG. 5C). As for a polishing method used here, for example, chemical mechanical polishing (CMP) or buff polishing may be listed. In conducting buff polishing, for example, it is preferred that a #400, 600 or 800 buff be used, and using a #600 buff is even more preferable. In doing so, conductive circuit (14₂U) is formed as are via conductors (14₁U), which connect conductive circuit (14₂U) and conductive circuit (12U); also, conductive circuit (14₂L) is formed as are via conductors (14₁L), which connect conductive circuit (14₂L) and conductive circuit (12L).

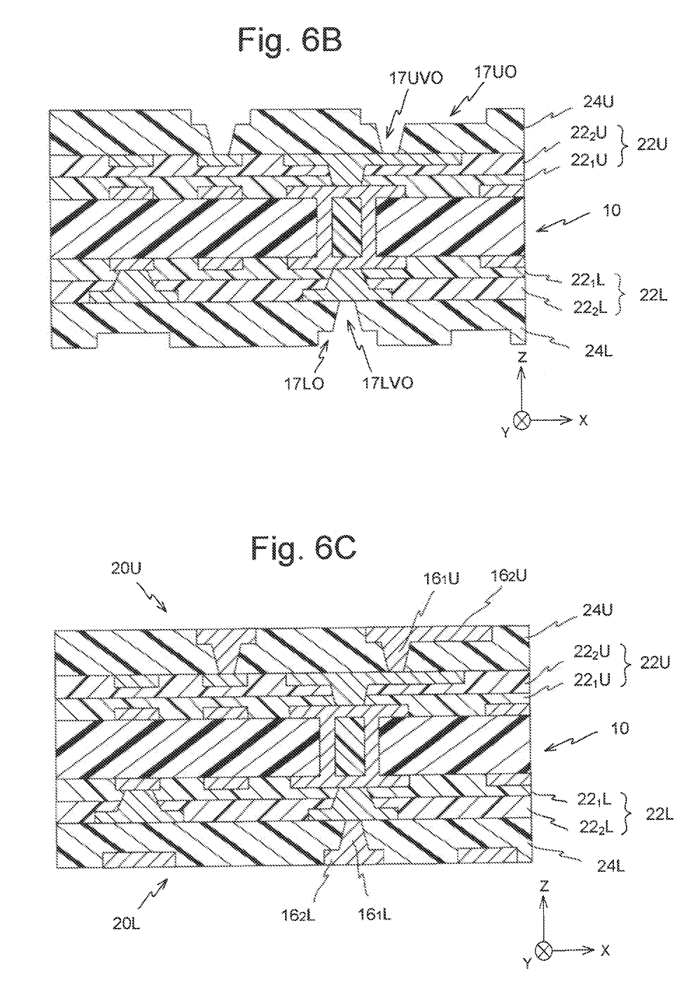

Next, resin insulation layer (24U) is formed to cover the surfaces of the above-described resin insulation layer (22U) and conductive circuit (14₂U); and resin insulation layer (24L) is formed to cover the surfaces of the above-described resin insulation layer (22L) and conductive circuit (14₂L) (see FIG. 6A).

Then, the same processes as above, first laser process and second laser process, are conducted on resin insulation layers (24U, 24L) to form via-conductor opening portions (17UVO, 17LVO) for interlayer connection, and conductive-circuit opening portions (17UO, 17LO) (see FIG. 6B). To form via-conductor opening portions (17UVO, 17LVO), any laser selected from among a group of carbon dioxide gas lasers, exima lasers and YAG lasers may be used. Also, to form conductive-circuit opening portions (17UO, 17LO), either a UV laser or an exima laser may be used.

Resin insulation layers (24U, 24L) may be formed by laminating interlayer films for build-up wiring, for example, “ABF” (made by Ajinomoto Fine Techno, Co., Ltd.) or the like, on the support member, and then by thermosetting them approximately at 150-200° C. for 150-210 minutes. If a photosensitive resin is used to form resin insulation layers (24U, 24L), the resin is exposed to light and developed. Then, in the same process as above, via-conductor opening portions (17UVO, 17LVO) and conductive-circuit opening portions (17UO, 17LO) may be formed.

In the following, catalytic nuclei are formed on the surfaces of resin insulation layers (24U, 24L), and electroless plating and electrolytic plating are performed under the same conditions as above to form plated films. Then, those films are polished in the same way as above. Accordingly, laminated sections (20U, 20L) are formed (see FIG. 6C).

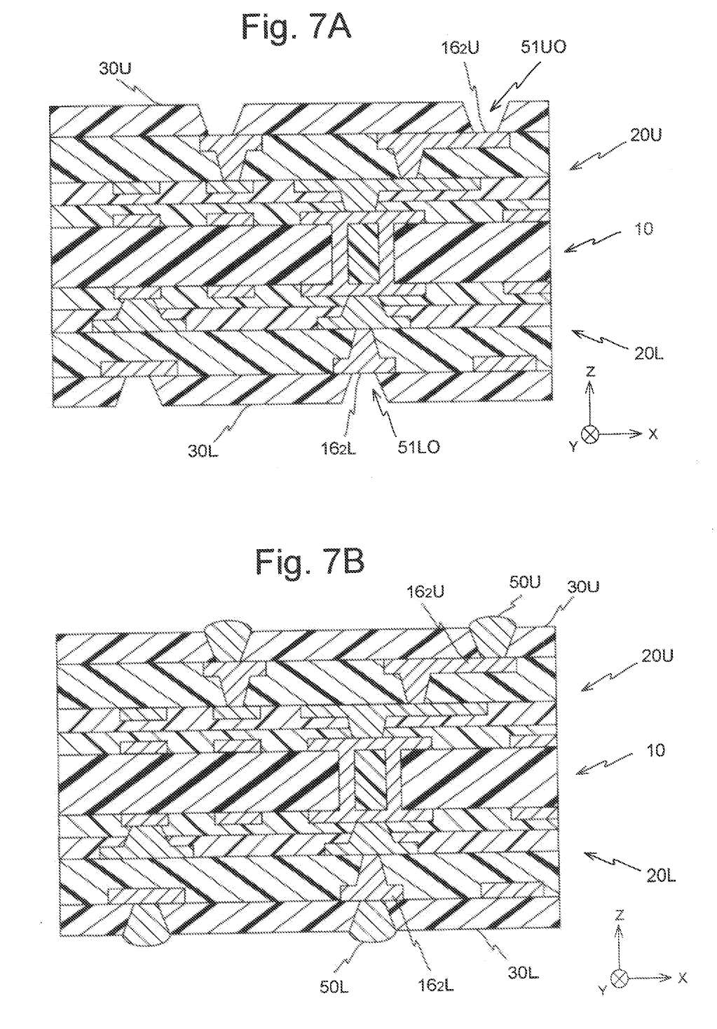

In the following, solder resist (30U, 30L) are formed on the surfaces of laminated sections (20U, 20L) respectively. Such solder resists (30U, 30L) may be formed, for example, by applying a commercially available solder-resist composition and drying it. Then, using a mask, solder resists (30U, 30L) are exposed to light and developed to form opening portions (51UO, 51LO) respectively, which expose part of the conductive circuits (see FIG. 7A).

Here, conductive circuits (16₂U, 16₂L), exposed through opening portions (51UO, 51LO) formed in the solder resists, work as pads. Then, on such pads, either solder paste is printed or solder balls are loaded and reflowed, and solder members (solder bumps) (50U₁, 50U₂) and (50L₁, 50L₂) are formed (see FIG. 7B). As a result, by means of such solder members (50U, 50L), the printed wiring board will be electrically connected to other substrates.

As described so far, in multilayer printed wiring board (100) of the First Embodiment, resin insulation layers (22U, 22L), in which conductive circuits 12U (12L) and conductive circuits 14₂U (14₂L) are embedded, are formed using resins containing inorganic particles with different particle diameters. Accordingly, around conductive circuits 14₂U (14₂L) which are the second conductive circuits formed after resin insulation layers 22U (22L) were formed, resin layers (second resin layers) 22₂U (22₂L) containing inorganic particles with relatively small particle diameters may be arranged. As a result, for example, when recessed portions 15UO (15LO) for conductive circuits are formed using a laser in resin layers 22₂U (22₂L) containing inorganic particles with smaller particle diameters, even if the inorganic particles fall off from the resins, the roughness of the surfaces of the resultant recessed portions should be small.

On the other hand, resin layers (first resin layers) 22₁U (22₁L) that are formed with resin containing particles with a relatively large particle diameter have smaller specific surfaces, and thus the liquidity of such resin increases accordingly. As a result, resin layers 22₁U (22₁L) may be filled completely between lines of conductive circuits 12U (12L) as first conductive circuits. Therefore, flat interlayer insulation layers 22U (22L) may be formed easily.

Furthermore, if the recessed portions formed by a laser are less roughened, the surface configuration of the wiring formed in such recessed portions will be less roughened. Accordingly, degradation of signal transmission under the skin effect will be suppressed. For example, if a conductive substance enters the gaps between inorganic particles such as filler and an insulative substance such as resin, or if a conductive substance enters the gaps formed after the inorganic particles fell off as above, then insulation between wiring lines declines. However, by making a structure such as above, a decrease in wiring insulation may be suppressed, and excellent insulation between wiring lines may be secured even when the line/space (L/S) is small and the pitch interval is narrow.

### Second Example Embodiment

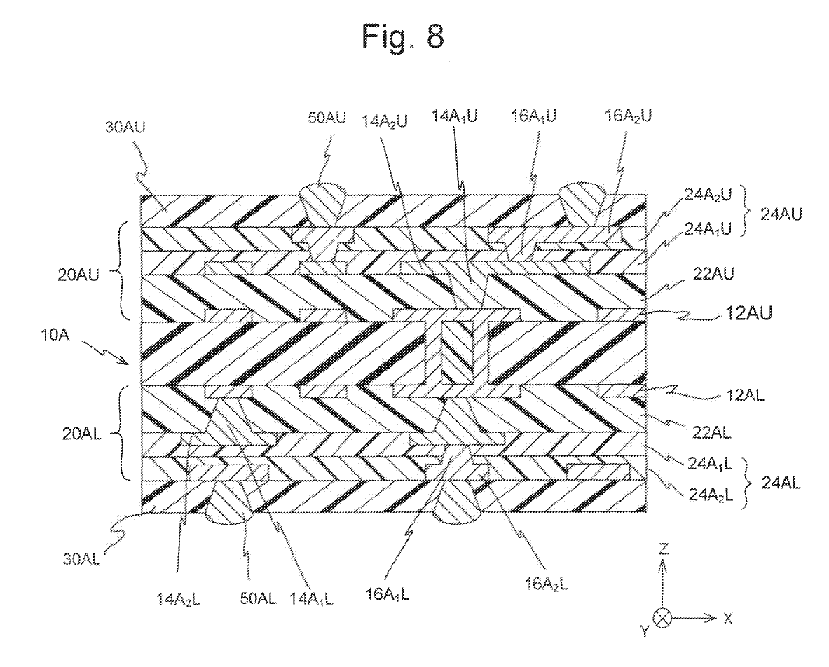

Next, the Second Embodiment is described. FIG. 8 shows a structure of printed wiring board (100A) according to the Second Embodiment of the present invention; core substrate (10A), laminated sections (20AU, 20AL), solder resist (30AU, 30AL) and solder members (solder bumps) (50AU, 50AL), which structure printed wiring board (100A), are shown to illustrate their positional relationships.

In the following, printed wiring board (100A) is described in detail.

As shown in FIG. 8, printed wiring board (100A) has the following: (a) core substrate (10A); (b) laminated section (20AU) formed on the (+Z) direction side of core substrate (10A); (c) solder member (50AU) arranged on conductive circuit (16A₂U), including a pad portion, which is formed on the (+Z) direction-side surface (first surface) of the outermost layer among the resin insulation layers in laminated section (20AU); (d) solder resist (30AU) formed on the (+Z) direction-side surface of laminated section (20AU); (e) laminated section (20AL) formed on (−Z) direction-side of core substrate (10A); (f) solder member (50AL) arranged on conductive circuit (16A₂L), including a pad portion, which is formed on the (−Z) direction-side surface (second surface) of the outermost layer among the resin insulation layers in laminated section (20AL); and (g) solder resist (30AL) formed on the (−Z) direction-side surface of laminated section (20AL).

Namely, compared with printed wiring board (100) described above according to the First Embodiment, printed wiring board (100A) of the Second Embodiment differs only in that it has laminated section (20AU) instead of laminated section (20U), and laminated section (20AL) instead of laminated section (20L). The following description mainly focuses on such differences.

Laminated section (20AU) has the following: (i) resin insulation layer (22AU) as an “insulative material” formed on the (+Z) direction side of core substrate (10A); (ii) conductive circuit (14A₂U) formed on the (+Z) direction-side surface of resin insulation layer (22AU); and (iii) via conductor (14A₁U) which electrically connects conductive circuit (12AU) and conductive circuit (14A₂U).

Furthermore, laminated section (20U) has the following: (iv) resin insulation layer (24AU) formed on the (+Z) direction-side surfaces of insulation layer (22AU) and conductive circuit (14A₂U); (v) conductive circuit pad (16A₂U) formed on the (+Z) direction-side surface of resin insulation layer (24AU); and (iii) via conductor (16A₁U) which electrically connects conductive circuit (14A₂U) and conductive circuit (16A₂U).

As shown in FIG. 8, resin insulation layer (24AU) is not formed with a single resin layer, but with two kinds of resin layer (24A₁U, 24A₂U). Namely, on the (+Z) direction-side surface of resin insulation layer (22AU), resin layer (24A₁U) (first insulation layer) containing inorganic particles with the same particle diameter as above-described resin layer (22₁U) is formed; and on the (+Z) direction-side surface of resin insulation layer (24A₁U), resin layer (24A₂U) (second insulation layer) is formed practically without containing any inorganic particles.

Laminated section (20AL) is formed the same as above-described laminated section (20AU) except that the direction in which it is laminated is (−Z) direction. Therefore, to refer to a structural element of laminated section (20AL) that corresponds to that of laminated section (20AU), an “L” is attached at the end so that it can be distinguished from a structural element of laminated section (20AU) with a “U” attached at the end.

The configurations of conductive circuit (12AU, 14A₂U, 16A₂U) and the positions where via conductors (14A₁U, 16A₁U) are formed usually differ from the configurations of conductive circuit (12AL, 14A₂L, 16A₂L) and the positions where via conductors (14A₁L, 16A₁L) are formed.

Also, the same as between resin insulation layers 22U (22L) and resin insulation layers 24U (24L) in the First Embodiment, a wiring layer, which is made up of a resin insulation layer, a conductive circuit and via conductors, may be arranged in one or more layers between resin insulation layers 22AU (22AL) and resin insulation layers 24AU (24AL).

As shown in FIG. 8, according to the Second Embodiment, conductive circuit (16A₂U) is embedded in resin insulation layer (24AU) to be set on substantially the same level as the (+Z) direction-side surface (first surface) of the insulation layer. However, if more wiring layers are further formed, part of such wiring layers may be formed on the (+Z) direction-side surface (first surface) of a resin insulation layer.

Also, according to the Second Embodiment, conductive circuit (16A₂L) is embedded in resin insulation layer (24AL) to be set on substantially the same level as the (−Z) direction-side surface of the insulation layer. However, if more wiring layers are further formed, part of such wiring layers may be formed on the (−Z) direction-side surface of each resin insulation layer.

Next, manufacturing printed wiring board (100A) of the Second Embodiment is described according to an example that uses a support member having a conductive layer on both of its surfaces.

When manufacturing printed wiring board (100), the same as in the above First Embodiment, core substrate (10) is manufactured first, using support member (BS) as a starting material (see FIGS. 2A-3C).

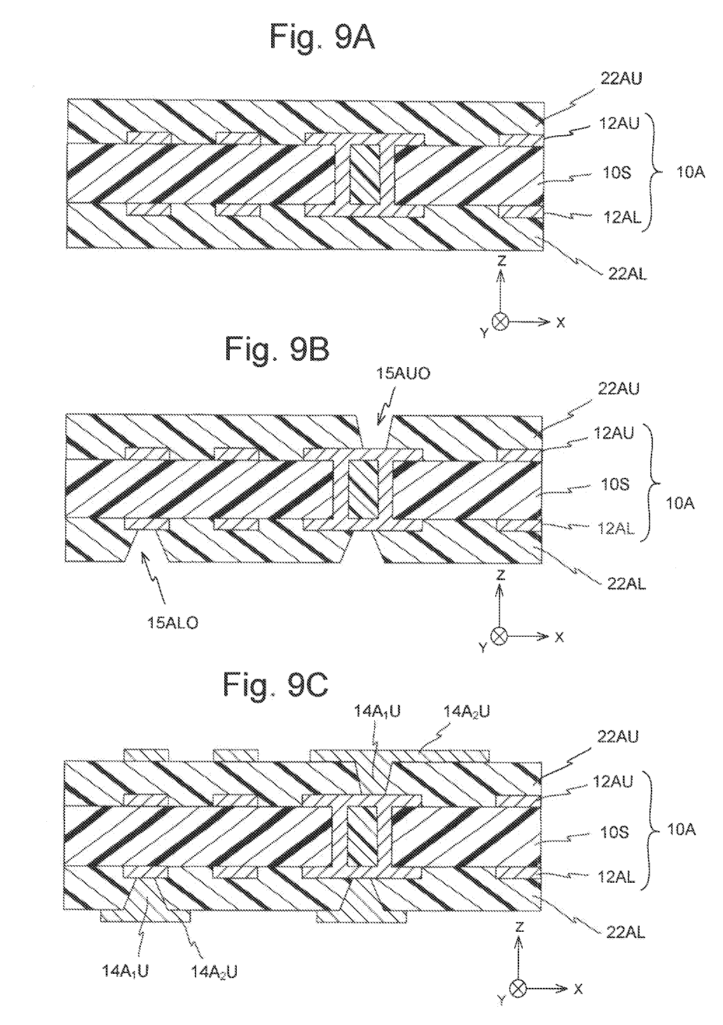

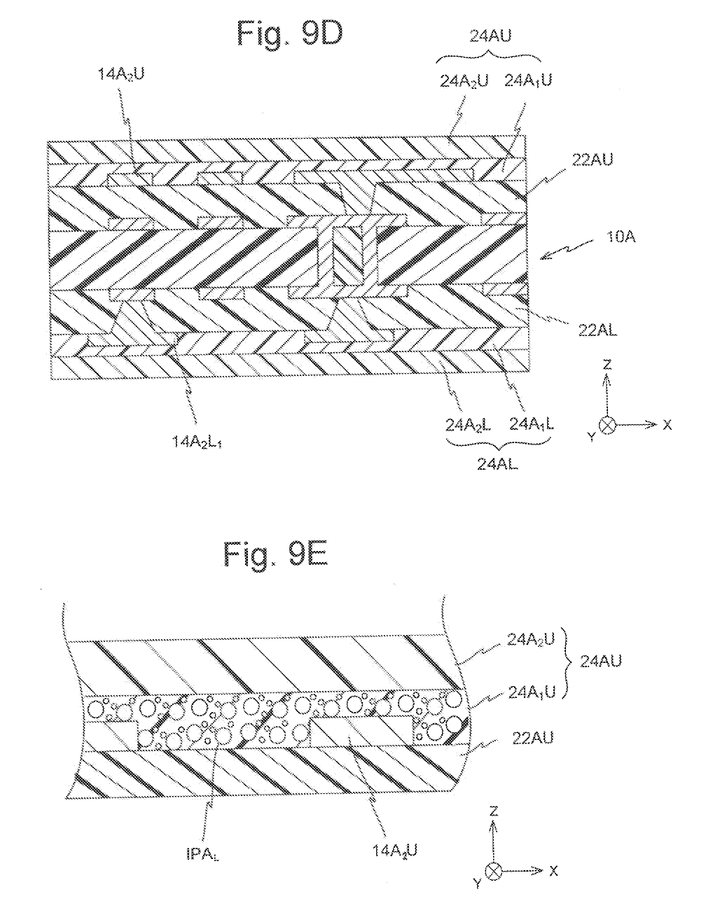

Next, using, for example, a resin insulation film (ABF, made by Ajinomoto Fine Techno, Co., Ltd.), resin insulation layer (22AU) is formed to cover each (+Z) direction-side surface of conductive circuit (12AU) formed as above and areas of support member (10S) exposed through etching. Resin insulation layer (22AL) is also formed on each (−Z) direction-side surface of conductive circuit (12AL) and areas of support member (10S) exposed through etching (see FIG. 9A).

Such resin insulation layers (22AU, 22AL) are formed under the above-described conditions.

Then, under the same conditions for making opening portions (17UVO, 17LVO) in the First Embodiment, opening portions (15AUO, 15ALO) are formed to make vias (14A₁U) for interlayer connection (see FIG. 9B). A laser may be used to form such opening portions. To form such via-opening portions, for example, a CO₂ laser may be used.

In the following, under the same conditions described above, conductive circuits (14A₂U) are formed by a semi-additive method or a subtractive method on the (+Z) direction-side surface of resin insulation layer (22AU) and on the (−Z) direction-side surface of resin insulation layer (22AL) (see FIG. 9C).

Then, using a film made by integrating an interlayer insulation film, the same type of interlayer insulation film as used in making first insulation layers (22₁U, 22₁L) in the First Embodiment, and an interlayer insulation film containing practically no inorganic particles, first insulation layer (24A₁U), second insulation layer (24A₂U), first insulation layer (24A₁L) and second insulation layer (24A₂L) are formed on the (+Z) direction-side surface of conductive circuit (14A₂Uᵢ) and on the (−Z) direction-side surface of conductive circuit (14A₂Lᵢ) (see FIGS. 9D and 9E).

Here, to ensure excellent performance when filling between lines of conductive circuits 16A₂U (16A₂L), the thickness of first insulation layers 24A₂U (24A₁L) is preferred to be made greater than the thickness of conductive circuits 16A₂U (16A₂L). Specifically, the same as in first insulation layers 22₂U (22₁L) in the First Embodiment, it is preferred to be set at approximately 10-20 μm. In second insulation layer 24A₂U (24A₂L), conductive-circuit recessed portions are formed in the later-described method. The resin between recessed portions formed herein will insulate between lines of the conductive circuit which are adjacent on a plane surface.

For resin insulation layers (24AU, 24AL), the same as in resin insulation layers (22U, 22L) in the above-described First Embodiment, for example, multiple sheets of interlayer insulation films or semi-cured resin sheets such as prepreg or the like may be used. Also, from a point of simplifying the process, it is preferred to use a sheet of film made by bonding multiple interlayer insulation films or the like, the same as in the First Embodiment.

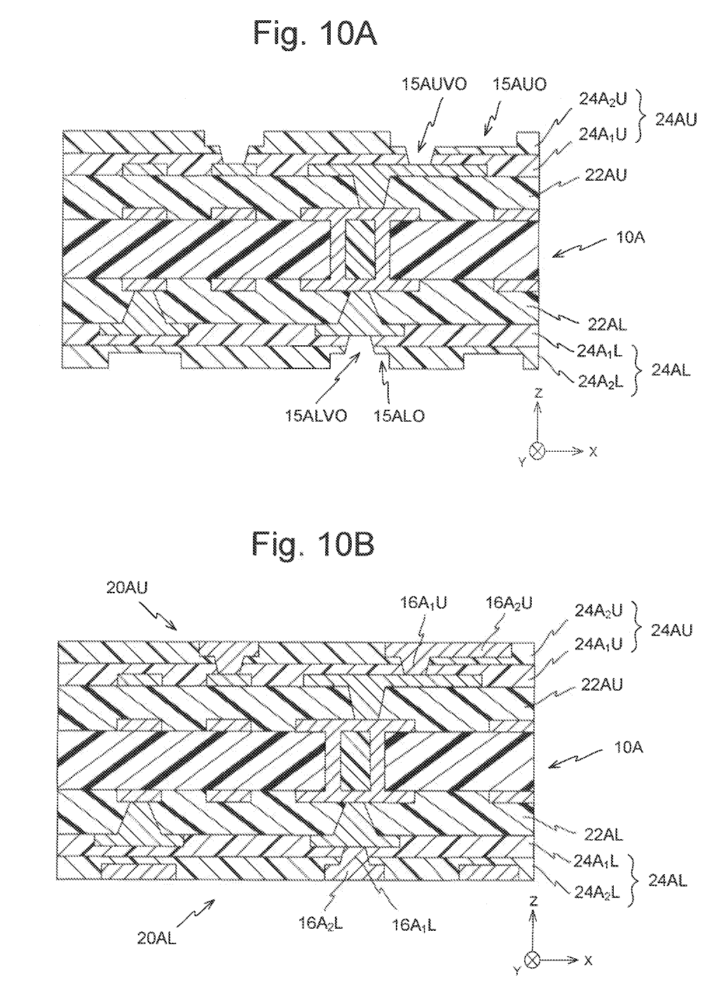

After that, on the (+Z) direction-side surface of the above-formed resin insulation layer (24AU) and the (−Z) direction-side surface of (24AL), via-conductor opening portions (15AUVO, 15ALVO) for interlayer connection, and conductive-circuit opening portions (15AUO, 15ALO) are formed. Then, plated films are formed by electroless plating and electrolytic plating, then polished, the same way as in the process for resin insulation layers (22U, 22L) in the above First Embodiment (see FIGS. 10A, 10B).

Portions of conductive circuits (16A₂U, 16A₂L), formed in the resin insulation layers (outermost layers: resin insulation layers (24AU, 24AL) in the Second Embodiment) on which solder resists will be formed later, are used as pads for solder members (50AU, 50AL).

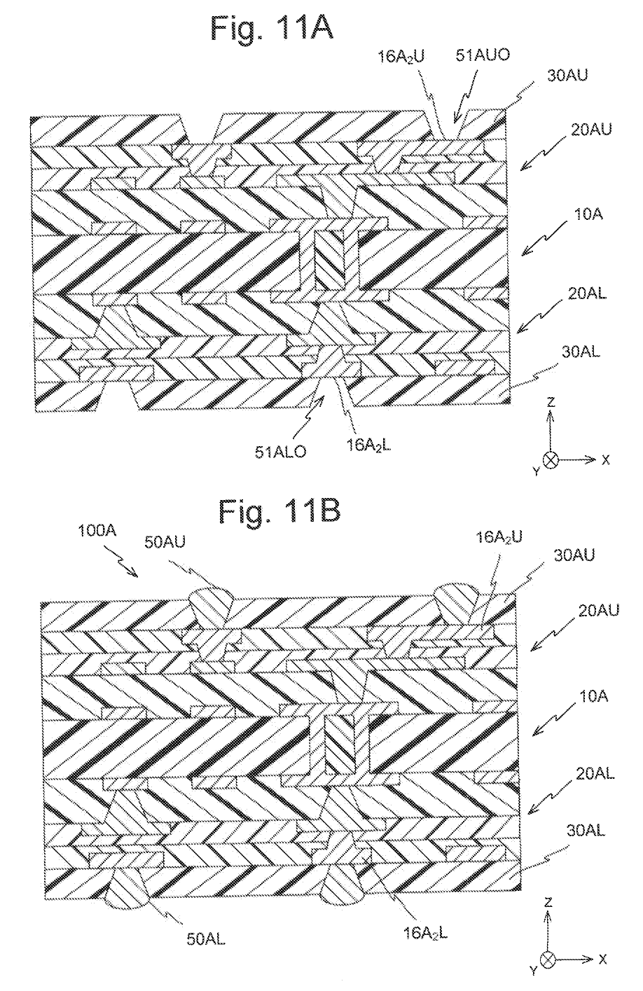

Next, solder resist (30AU) is formed on resin insulation layer (24A₂U) (the (+Z) direction-side surface) and solder resist (30AL) is formed on resin insulation layer (24A₂L) (the (−Z) direction-side surface) (see FIG. 11A). Then, in solder resists (30AU, 30AL), opening portions (51AUO, 51ALO) are formed to partially expose component-mounting pads in conductive circuits (16A₂U, 16A₂L) (see FIG. 11A).

In the following, on the exposed component-mounting pads, solder members (solder bumps) (50AU, 50AL) are formed. Accordingly, printed wiring board (100A) is manufactured (see FIG. 11B).

According to multilayer printed wiring board (100A) of the Second Embodiment, the same effects as in the First Embodiment may be achieved.

In the Second Embodiment, in the above first laminated sections, the number of conductive layers having embedded wiring was one. However, such layers are not limited to a specific number. Also, all the conductive layers of laminated sections may be formed as embedded wiring; or they may be mixed with a layer having wiring formed by a semi-additive method.

### Third Example Embodiment

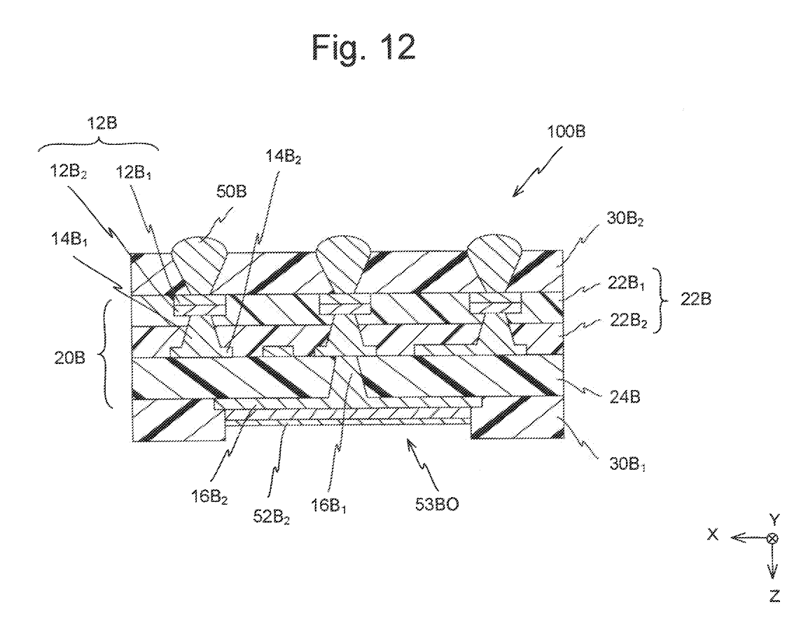

Next, the Third Embodiment is described. FIG. 12 shows a structure of printed wiring board (100B) according to the Third Embodiment of the present invention; laminated section (20B), solder resists (30B₁, 30B₂), solder members (50B, 52B) and so forth, which structure printed wiring board (100B), are shown to illustrate their positional relationships.

In the following, printed wiring board (100B) is described in detail.

As shown in FIG. 12, printed wiring board (100A) has the following: (a) laminated section (20B); (b) solder member (50B) arranged on component-mounting pad (hereinafter, simply referred to as “pad”) (12B), which is formed on the (−Z) direction-side surface (first surface) of the outermost layer among resin insulation layers in laminated section (20B); (c) solder resist (30B₂) formed on the (−Z) direction-side surface of laminated section (20B); (d) pad (52B) formed on the (+Z) direction-side surface (second surface) of the outermost layer among resin insulation layers in laminated section (20B); and (g) solder resist (30B₁) formed on the (+Z) direction-side surface of laminated section (20B).

Laminated section (20B) has the following: (i) pad (12B); (ii) resin insulation layer (22B) where pad (12B) is embedded on its (−Z) direction-side surface (first surface); (iii) conductive circuit (14B₂) formed on the (+Z) direction-side surface (second surface) of resin insulation layer (22B); and (iv) via conductor (14B₁), which electrically connects pad (12B) and conductive circuit (14B₂).

Furthermore, laminated section (20B) has the following: (v) resin insulation layer (24B) formed on the (+Z) direction-side surfaces of resin insulation layer (22B) and conductive circuit (14B₂); (v) conductive circuit (16B₂) formed on the (+Z) direction-side surface of resin insulation layer (24B); and (iii) via conductor (16B₁), which electrically connects conductive circuit (14B₂) and conductive circuit (16B₂).

As shown in FIG. 12, conductive circuit (12BL) is not formed with a single metal, but with two kinds of metal layers (12B₁) and (12B₂). Composition of such metal layers (12B₁) and (12B₂) or the like will be described later.

Also, resin insulation layer (22B) is not formed with a single resin, but is formed with two types of resin layers (22B₁) and (22B₂), the same as in resin insulation layer (22U) described above in the First Embodiment. Namely, on the (−Z) direction-side surface of resin insulation layer (22B), resin layer (22B₁) (first insulation layer) is formed, which contains inorganic particles having the same particle diameters as in the above-described resin layer (22₁U); and on the (+Z) direction-side surface of resin insulation layer (22B,), resin layer (22B₂) (second insulation layer) is formed, which contains inorganic particles having the same particle diameters as in the above-described resin layer (22₂U).

Also, the same as between resin insulation layers 22U (22L) and resin insulation layers 24U (24L) in the First Embodiment, a wiring layer, which is made up of a resin insulation layer, conductive circuit and via conductors, may be arranged in one or more layers between resin insulation layer (22B) and resin insulation layer (24B).

As shown in FIG. 12, in the Third Embodiment, conductive circuit (14B₂) is embedded in resin insulation layer (22B) to be set substantially on the same level as the (+Z) direction-side surface of the resin layer. However, if more wiring layers are further formed, a semi-additive method or subtractive method may also be used.

Next, a method for manufacturing printed wiring board (100B) according to the Third Embodiment is described.

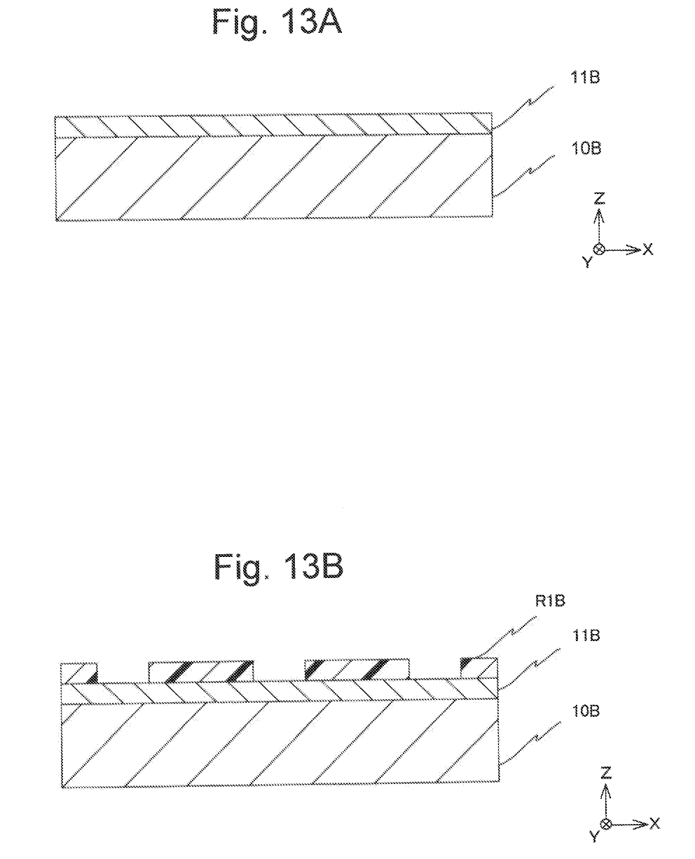

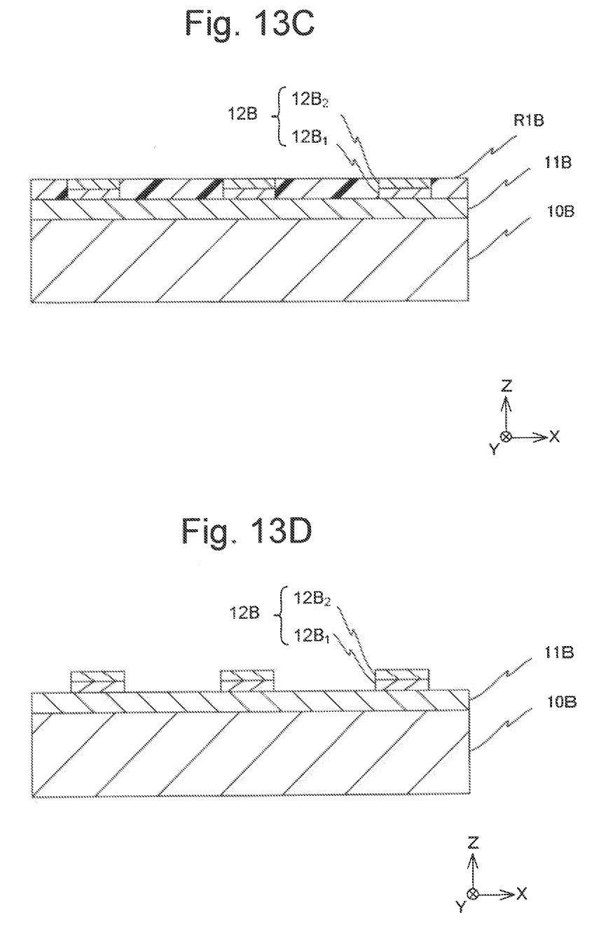

When manufacturing printed wiring board (100B), first, for example, on metal plate (110B) such as a copper plate or the like, seed layer (11B) made with multiple different metals is formed (see FIG. 13A). For example, on the first surface (on the (+Z) direction-side surface) of a copper plate, a chrome layer is formed first. Then, on the first surface of the chrome layer, a copper layer is formed to make seed layer (11B). To form seed layer (11B), a method such as electroless plating, sputtering or deposition may be used.

As for the metal to form metal plate (10B), a metal that can be etched by an etching solution but whose etching speed is substantially slow may be used instead of chrome.

Then, after forming seed layer (11B), resist pattern (R1B) is formed on the (+Z) direction-side surface of seed layer (11B) (see FIG. 13B). Then, on the surface of seed layer (11B), exposed through resist pattern (R1B), metal layer (12B₁) is formed (see FIG. 13C). On the (−Z) direction-side surface of metal layer (12B₂), solder member (50B) will be formed.

Metal layer (12B₁) is formed with a gold (Au) plated film, palladium (Pd) plated film and nickel (Ni) plated film in that order, starting from the surface of seed layer (11B) in the (+Z) direction. Those plated films may be formed, for example, by electrolytic plating.

Also, as for metal layer (12B₁), a compound layer of Au—Ni may be formed. Such metal layer (12B₁) functions as a protective film, as described later, which suppresses oxidation of component-mounting pads, and shows an effect which enhances the solder wettability.

Next, on metal layer (12B₁), metal layer (12B₂) made of copper, for example, is formed by electrolytic plating, for example (see FIG. 13C). After that, using a conventional method, the resist is removed (see FIG. 13D). Accordingly, pads (12B) are formed.

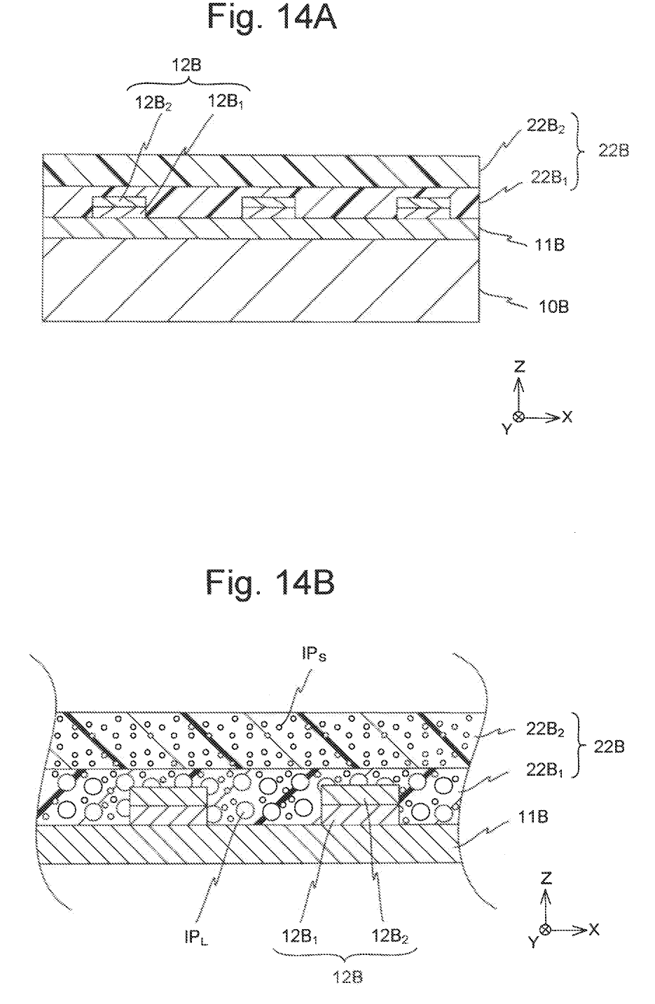

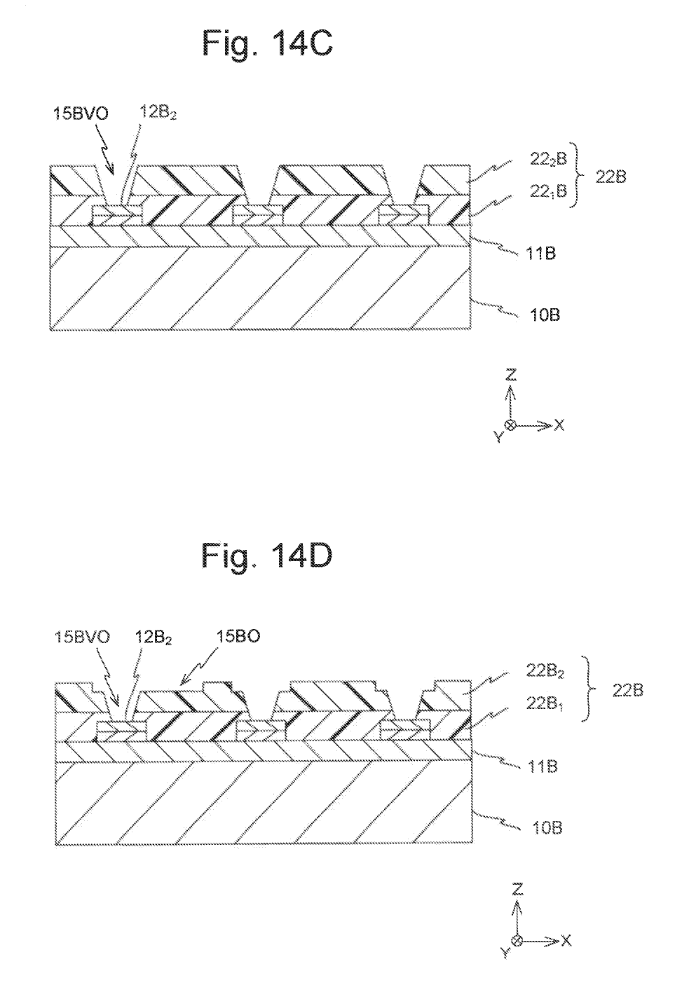

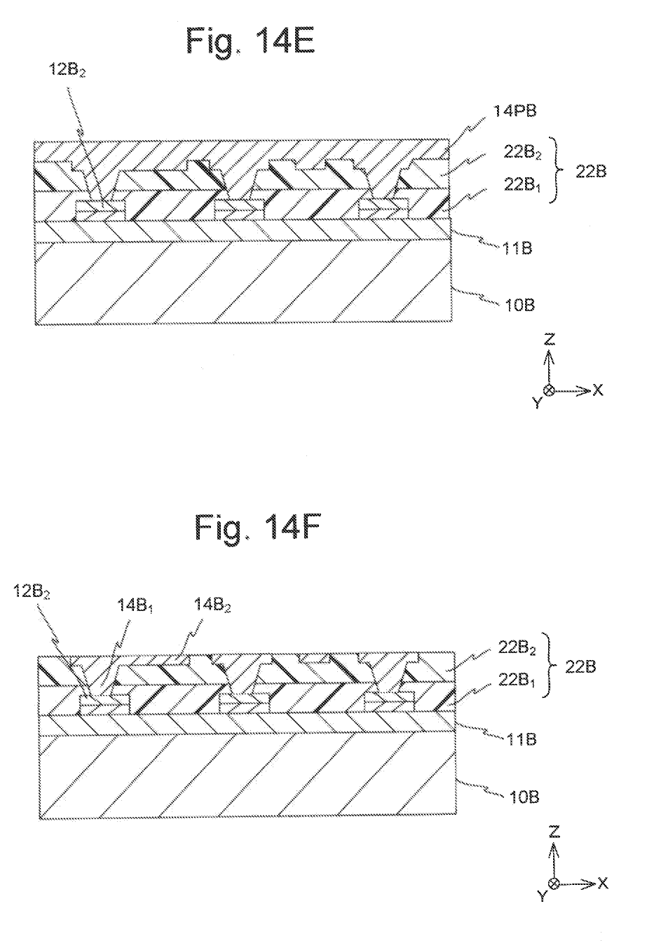

Next, resin insulation layer (22B) is formed so as to cover each (+Z) direction-side surface of above-formed pads (12B) and seed layer (11B). Resin insulation layer (22B) has first insulation layer (22B₁) made with a resin containing first inorganic particles (IP_{L}), and second insulation layer (22B₂) made with a resin containing second inorganic particles (IP_{S}) which is formed on the (+Z) direction-side surface of the first insulation layer and has an average particle diameter smaller than that of the first inorganic particles (see FIGS. 14A, 14B).

First insulation layer (22B₁) is formed the same way as first insulation layers 22₁U (22₁L) in the above First Embodiment. Also, second insulation layer (22B₂) is formed the same way as first insulation layers 22₂U (22₂L) in the above First Embodiment.

Next, as shown in FIG. 14C, a predetermined number of via-conductor openings (15BVO) for interlayer connection are formed. As for a laser to be used for such openings, a carbon-dioxide gas laser, an exima laser, a YAG laser, a UV laser or the like may be listed. When openings are formed by a laser, a protective film such as a PET (polyethylene terephthalate) film may be used.

In the following, as shown in FIG. 14D, a second laser process using a UV laser or an exima laser is conducted to form conductive-circuit recessed portions (15BO).

When conducting a second laser process, it is preferred that the resin residue remaining at the bottom of via-conductor openings (15BVO) be removed. By doing so, connection reliability between later-formed via conductors and pads may be enhanced.

Also, after forming conductive-circuit recessed portions (15BO), the member may be immersed in a permanganate solution to roughen the surface of resin insulation layer (22B₂).

Next, plated layer (14PB) is formed, for example, by performing plating under the above conditions as shown in FIG. 14E. The plated layer is made up of an electroless plated film (electroless copper-plated film) and an electrolytic plated film (electrolytic copper-plated film) formed on the electroless plated film, and covers the surface of resin insulation layer (22B₂) including via-conductor opening portions (15BVO) and recessed portions (15BO).

Next, plated layer (14PB) is polished until the surface of resin insulation layer (22B₂) is exposed. Accordingly, via conductors (14B₁) and conductive circuit (14B₂) are formed to be embedded in resin insulation layer (22B) (see FIG. 14F). As for the polishing method used here, for example, a chemical mechanical polishing (CMP) or buff polishing or the like may be listed. In doing so, conductive circuit (14B₂) is formed as are via conductors (14B₁), which connect conductive circuit (14B₂) and pads (12B).

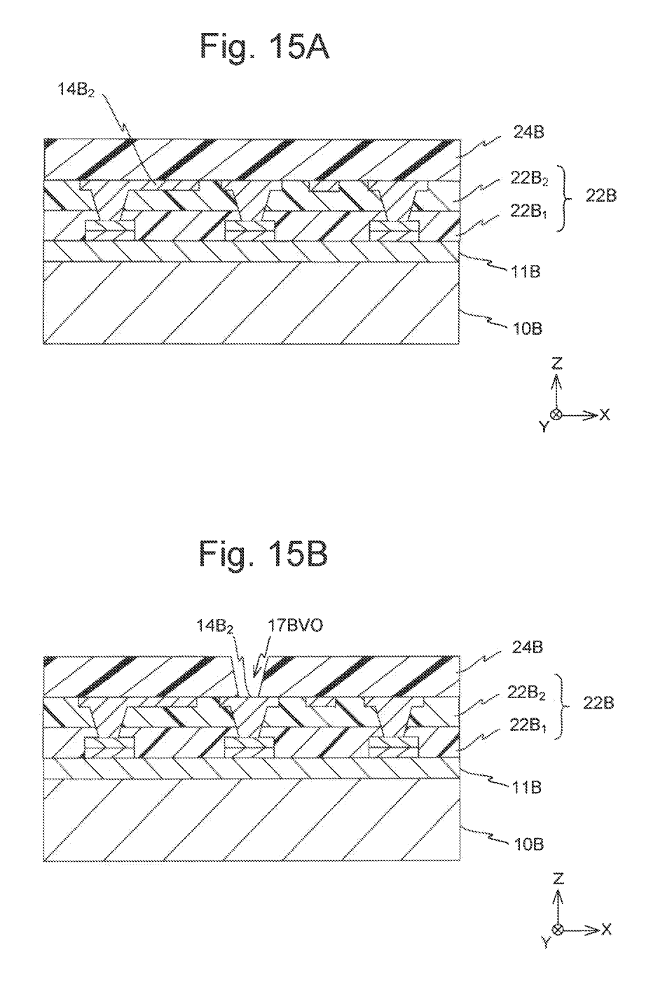

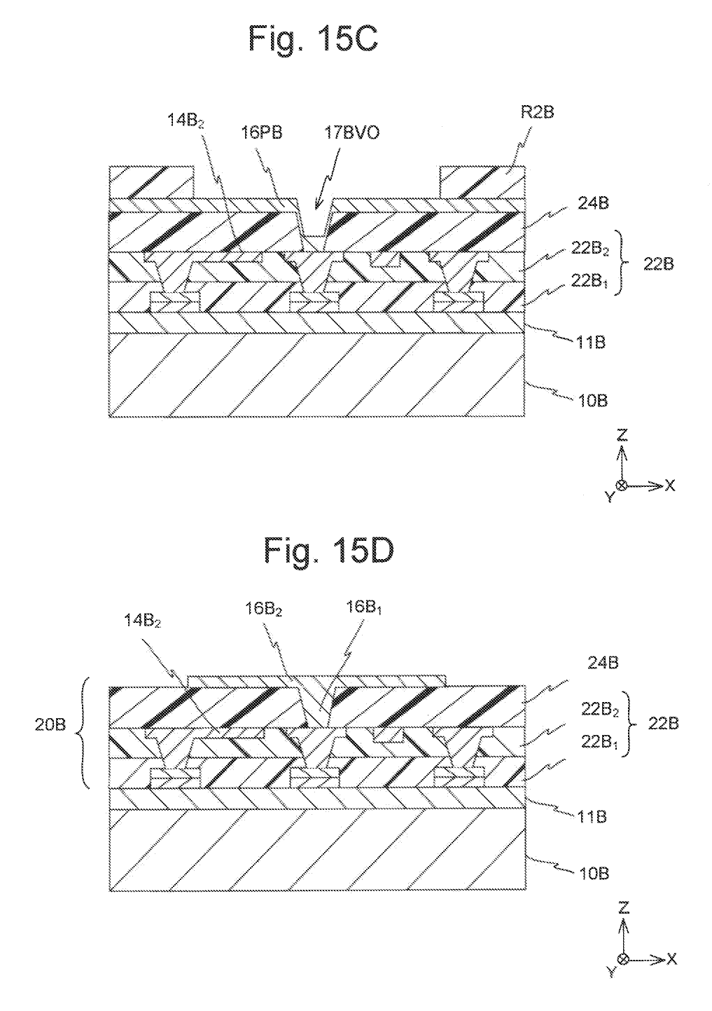

Next, resin insulation layer (24B) is formed to cover the surfaces of above-formed resin insulation layer (22B) and conductive circuit (14B₂) (see FIG. 15A). Then, the same process as in the above first laser process is conducted on resin insulation layer (24B) to form via-conductor opening portions (17BVO) for interlayer connection (see FIG. 15B).

Here, to form via-conductor opening portions (17BVO), any laser selected from a group of carbon-dioxide gas lasers, exima lasers and YAG lasers may be used.

Also, resin insulation layer (24B) may be formed by laminating, for example, an ABF (made by Ajinomoto Fine Techno Co., Ltd.) under the same conditions as above. If a photosensitive resin is used for resin insulation layer (24B), the film is exposed to light and developed to form via-conductor opening portions (17BVO) the same as above.

In the following, catalytic nuclei are formed on the surface of resin insulation layer (24B), and plated film (16PB) is formed by electroless plating (see FIG. 15C). Then, plating resist (R2B) is formed on electroless plated film (16PB) (see FIG. 15C).

Next, electrolytic plated film is formed in the areas where plating resist (R2B) is not formed and via-conductor opening portions are filled with electrolytic plating. In the following, the plating resist is removed, and the electroless plated film under the plating resist is also removed. Accordingly, conductive circuit (16B₂) is formed as are via conductors (16B₁), which connect conductive circuit (16B₂) and conductive circuit (14B₂).

Here, the surfaces of resin insulation layer (24B) and conductive circuit (16B₂) are each preferred to be roughened. Such a roughening process may be conducted the same as in the above-described First Embodiment.

As a result, laminated section (20B) is formed on the (+Z) direction-side surface of seed layer (11B).

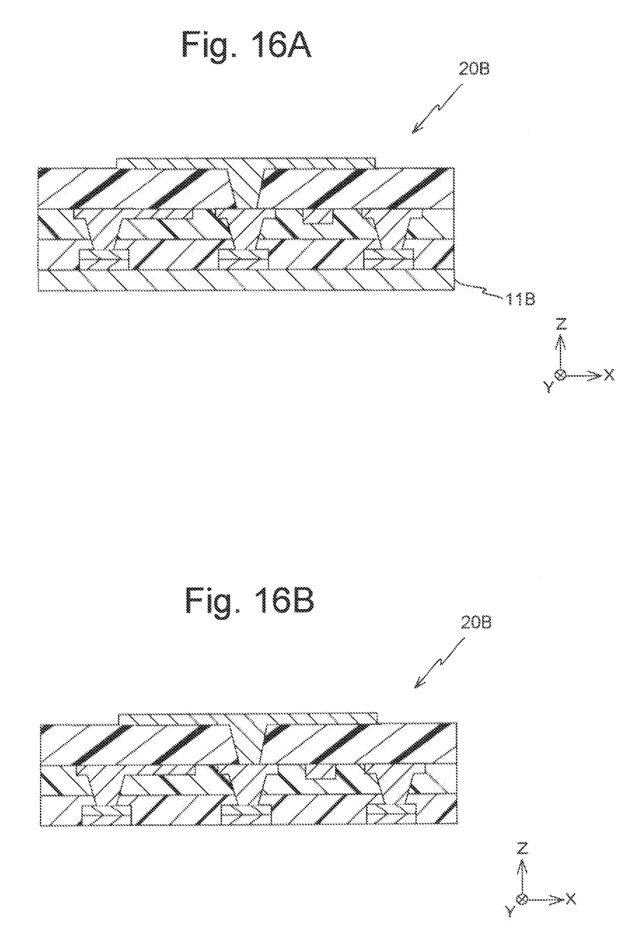

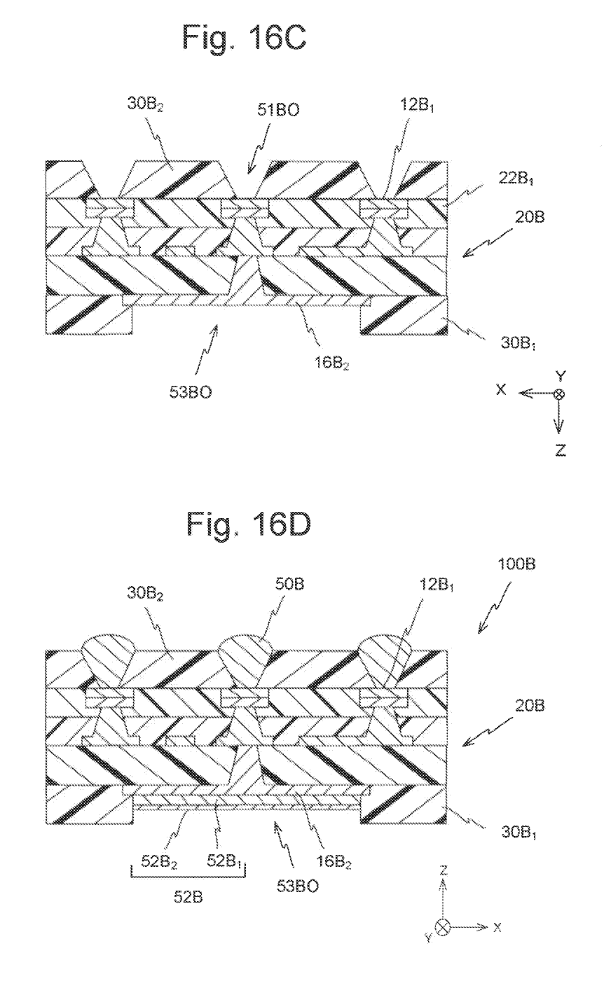

Next, metal plate (10B) is removed by etching or the like (see FIG. 16A). During that time, etching of the copper that forms metal plate (10B) is stopped at the chrome layer that forms seed layer (11B).

Then, above described seed layer (11B) is removed (see FIG. 16B). For example, if seed layer (11B) has been formed with a chrome layer and a copper layer in that order on the (+Z) direction-side surface of the insulation member, then seed layer (11B) is removed starting with the chrome layer and then the copper layer, in that order. In such a case, the chrome layer is removed using an etching solution which etches away the chrome layer but does not etch the copper layer. Then, the copper layer that forms the seed layer is removed using an etching solution that etches away the copper layer. In doing so, metal film (12B₁), which functions as a protective layer at pad (12B), is exposed on the first surface (the (−Z) direction-side surface) of resin insulation layer (22B) (see FIG. 16B). At that time, the first surface of resin insulation layer (22B) and the exposed surface of metal film (12B₁) are positioned substantially on the same level.

After seed layer (11B) is removed, solder resist (30B₁) is formed on resin insulation layer (22B) (the (+Z) direction-side surface), and solder resist (30B₂) is formed on resin insulation layer (22B) (the (−Z) direction-side surface) where pads (12B) are formed. Then, openings (53BO) to partially expose conductive pattern (16B₂) are formed in solder resist (30B₁), and openings (51BO) to partially expose pads (12B) are also formed in solder resist (30B₂) (see FIG. 16C).

In the following, solder member (solder bump) (50B) is formed on pad (12B) and solder plated film (52B) is formed on conductive circuit (16B₂) (see FIG. 16D). In FIG. 16D, solder plated film (52B) is shown as two layers (52B₁, 52B₂), but it may also be formed as one layer. The number of its layers is not limited specifically.

Accordingly, printed wiring board (100B) is manufactured.

As described above, according to multilayer printed wiring board (100B) of the above Third Embodiment, resin insulation layer (22B), in which pads (12B) and conductive circuit (14B₂) are embedded, is formed using resins containing inorganic particles with different particle diameters. Accordingly, around conductive circuit (14B₂) formed as the second conductive circuit after resin insulation layer (22B) is formed, resin layer (second insulation layer) (22B₂), containing inorganic particles with relatively small particle diameters, may be positioned.

As a result, for example, when conductive-circuit recessed portions (15BO) are formed using a laser in resin layer (22B₂), which contains inorganic particles with small particle diameters, and even if the inorganic particles fall off from the resin, the roughness of the surfaces of the resultant recessed portions should be small.

Also, resin layer (first resin layer) (22B₁), formed with resin containing inorganic particles with relatively large particle diameters, has a smaller specific surface, and thus the liquidity of the resin increases accordingly. As a result, resin layer (22B₁) may completely fill between the lines of conductive circuit (12B) as a first conductive circuit, and flat interlayer insulation layer (22B) may be formed easily.

On the other hand, if the recessed portions formed by a laser are less roughened, the surface configuration of the wiring formed in such recessed portions will be less roughened. Accordingly, deterioration of signal transmission under the skin effect will be suppressed. For example, if a conductive substance enters the gaps between inorganic particles such as filler and an insulative substance such as resin, or if a conductive substance enters the spaces formed after the inorganic particles fell as above, then insulation between wiring lines will be reduced. However, by making a structure such as above, a decline in wiring insulation may be suppressed, and excellent wiring insulation may be secured even when the line/space (L/S) ratio is small and the pitch interval is narrow.

### Fourth Example Embodiment

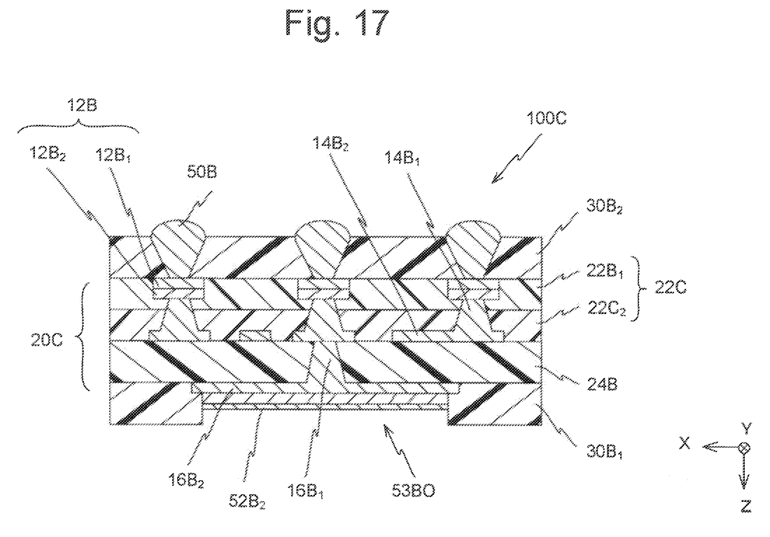

Next, the Fourth Embodiment is described. FIG. 17 shows a structure of printed wiring board (100C) according to the Fourth Embodiment of the present invention; laminated section (20C), solder resists (30B₁, 30B₂), solder members (50B, 52B) and so forth, which structure printed wiring board (100C), are shown to illustrate their positional relationships.

In the following, printed wiring board (100C) is described in detail.

As shown in FIG. 17, printed wiring board (100C), when compared with above-described printed wiring board (100B) (see FIG. 12) of the Third Embodiment, is different only in that it has laminated section (20C) instead of laminated section (20B).

In addition, laminated section (20C), when compared with laminated section (20B), is different only in that it has resin layer (22C₂) instead of resin layer (22B₂). Resin layer (22C₂) is formed the same way as above-described resin layer (24A₂) of the Second Embodiment. It is formed with resin practically having no inorganic particles.

Also, the same as between resin insulation layer (22B) and resin insulation layer (24B) in the Third Embodiment, a wiring layer, which is made up of a resin insulation layer, conductive circuit and via conductors, may be arranged in one or more layers between resin insulation layer (22C) and resin insulation layer (24B).

Next, a method for manufacturing printed wiring board (100C) according to the Third Embodiment is described.

When manufacturing printed wiring board (100C), the steps from forming seed layer (11B) on metal plate (10B) to forming pad (12B) are conducted the same way as in the Third Embodiment (see FIGS. 13A-13D).

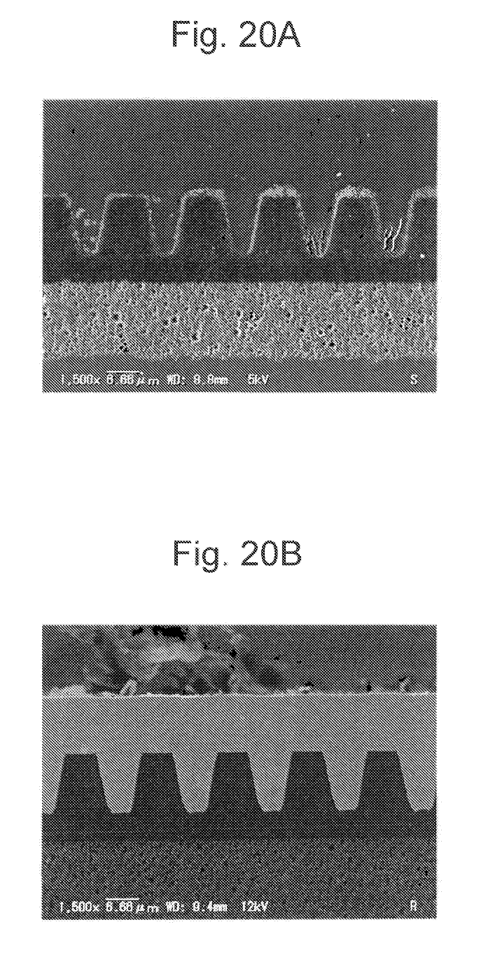

In the following, first insulation layer (22B₁) is formed using an insulative resin containing first inorganic particles (IP_{L}) so as to cover each (+Z) direction-side surface of above-formed pad (12B) and seed layer (11B). Then, on the (+Z) direction-side surface of the first resin insulation layer, second insulation layer (22C₂) is formed using a resin practically containing no inorganic particles (see FIGS. 20A, 20B). As a result, resin insulation layer (22C) is formed.

After that, the steps from forming via-conductor opening portions (15BVO) for interlayer connections to forming solder members (50B, 52B) are conducted the same way as in the Third Embodiment (FIGS. 14A-16D). Accordingly, printed wiring board (100C) is manufactured.

According to multilayer printed wiring board (100C) in the above Fourth Embodiment, the same effect as in the Third Embodiment may be achieved.

In the above Fourth Embodiment, the number of conductive layers having embedded wiring was set as two layers in the laminated section, the same as in the Third Embodiment. However, the number of such layers is not limited specifically. Namely, all the conductive layers in the laminated section may be formed with embedded wiring. In such a case, wiring using a semi-additive method is not employed.

### Examples

### Example 1

A. Preparing Resin Filler

The following were put in a container and mixed by blending them at room temperature to make a resin filler with a viscosity of 45-49 Pa·s at 23±1° C.: bisphenole F-type epoxy monomer (YL983, molecular weight=310, made by Japan Epoxy Resins Co., Ltd.) 100 weight parts; SiO₂ spherical particles whose surfaces are coated with a Silane coupling agent (CRS 1101-CE made by Atotec Japan, average particle diameter of 1.6 μm, and maximum particle diameter of 15 μm or smaller) 170 weight parts; and a leveling agent (Perenol S4, made by Sannopco Limited) 1.5 weight parts.

As a curing agent, an imidazole curing agent (2E4MZ-CN, made by Shikoku Chemicals Corporation) 6.5 weight parts was used.

B. Manufacturing a Multilayer Printed Wiring Board

(1) Manufacturing a Core Substrate

(1-1) Forming Support Member (BS)

(1) As for support member (BS), double-sided copper-clad laminate (BS) (product number: MCL-E679 FGR, made by Hitachi Chemical Co., Ltd.) was used where copper foils (FU, FL) with a thickness of 18 μm are laminated on both surfaces of a glass-epoxy plate with a thickness of 0.8 mm (see FIG. 2A).

Then, as shown in FIG. 2B, the copper-clad laminate was drilled to form through-holes (19) for through-hole conductors with an approximate inner diameter of 0.20 μm.

Next, the copper-clad laminate with through-holes (19) was immersed in a plating bath shown in Table (4) below at a bath temperature of 70° C. for 30 minutes. Accordingly, electroless copper-plated film was formed on copper foils (FU, FL) and on the inner-wall surfaces of through-holes (19).

TABLE 4
electroless plating bath composition (1)

| name of compound | amount | |
|---|---|---|
| EDTA | 150 | g/L |
| copper sulfate | 20 | g/L |
| HCHO | 30 | ml/L |
| NaOH | 40 | g/L |
| α,α'-bipyridyl | 80 | mg/L |
| PEG | 0.1 | g/L |

Then, using a plating bath shown in Table (5) below, electrolytic copper plating is performed under the conditions of 1.0 A/dm², power-on time of 30 minutes and bath temperature of 30° C. to form conductive layers (FUP, FLP) including through-hole conductors (TH), which were made of an electroless copper-plated film and an electrolytic copper-plated film on the electroless copper-plated film.

TABLE 5
electrolytic plating bath composition (1)

| name of compound | amount | |
|---|---|---|
| sulfuric acid | 180 | g/L |
| copper sulfate | 80 | g/L |
| additive* | 1 | ml/L |

*Cupracid GL (made by Atotec Japan)

(2) Then, as shown in FIG. 2D, the substrate with through-hole conductors (TH) was washed with water and dried. After that, a black-oxide treatment was conducted using a solution containing NaOH (10 g/L), NaClO₂ (40 g/L) and Na₃PO₄ (6 g/L) as a black oxide bath (oxidation bath); and a reduction treatment was conducted using a solution containing NaOH (10 g/L) and NaBH₄ (6 g/L) as a reduction bath. Accordingly, the surfaces of through-hole conductors (TH) were roughened (see FIG. 2D).

(3) Next, as shown in FIG. 2E, resin filler (11) described in above (A) was filled in through-hole conductors (TH) using the below method.

Namely, first, using a squeegee, resin filler (11) was pushed into through-hole conductors (TH), and was dried under conditions of 100° C. for 20 minutes. Then, one side of the substrate was belt-sanded using a #600 belt polishing paper (made by Sankyo-Rikagaku Co., Ltd.) so that resin filler (11) does not remain on the electrolytic copper-plated film. Then, the substrate was buff-sanded to remove scratches by the above belt-sander polishing. Such series of polishing were also conducted on the other surface of the substrate.

Then, heat treatments, each at 100° C. for an hour, at 120° C. for three hours, at 150° C. for an hour, and at 180° C. for seven hours, were conducted to form resin filler layers.

(4) Next, as shown in FIG. 2F, on both surfaces of electrolytic copper-plated films (FUP, FLP) and resin filler (11), plating treatment was performed using each plating bath described above under the same conditions to form conductive layers (12UP, 12LP) made with an electroless copper-plated film and an electrolytic copper-plated film.

Then, a photosensitive dry film was laminated and a photomask made of glass was placed thereon, exposed to light at 100 mJ/cm², and developed using a 0.75% sodium carbonate solution. Accordingly, etching resists with an approximate thickness of 15 μm were formed. Next, using a mixed solution of sulfuric acid and hydrogen peroxide, the areas where etching resist was not formed were etched, and then the etching resists were removed using a 5% potassium hydroxide solution. Accordingly, conductive circuits (12U, 12L) and through-hole-covering conductive layers were formed (see FIGS. 3A-3C).

(5) Next, after washing the above substrate with water and acid degreasing, soft etching was conducted. Then, by spraying an etching solution on both surfaces of the substrate, the surfaces of conductive circuits (12U, 12L) (including areas of the conductive circuits that cover resin filler (11)) were etched using an etching solution (MEC Etch Bond, made by Mec Co., Ltd.) that contains imidazole copper (II) complex 10 weight parts, glycolic acid 7 weight parts and sodium chloride 5 weight parts. Accordingly, entire surfaces of conductive circuits (12U, 12L) (including land surfaces of through-hole conductors (TH)) were roughened (not shown in the drawings).

(6) Then, as for a resin sheet to form resin insulation layers, the following was prepared; namely, a resin sheet was prepared which was made of a first insulation layer with an approximate thickness of 25 μm, a second insulation layer with an approximate thickness of 15 μm, first inorganic particles with an average particle diameter of 0.5 μm (the maximum particle diameter of 3.0 μm), and second inorganic particles with an average particle diameter of 0.02 μm (maximum particle diameter of 0.03 μm).

Then, the above resin sheet was laminated on both surfaces of core substrate (10) under conditions of pressure at 0.7 MPa, temperature at 100° C. and time of 30 seconds, and then thermoset at 180° C. for 30 minutes.

(7) Then, via-conductor openings were formed in the second insulation layer using a carbon-dioxide gas laser (see FIG. 5A). The carbon-dioxide gas laser used here was used under conditions of wavelength 10.4 μm, beam diameter 4.0 mm, single mode, pulse width 8.0μ, seconds and 1-3 shots (see FIG. 5A).

Next, using an exima laser, recessed portions for conductive circuits were formed under conditions of wavelength 308 nm or 355 nm (see FIG. 5A).

In the following, using a commercially available plating bath solution, electroless copper plating was performed to form an electroless copper-plated film with an approximate thickness of 0.3-1 μm. Then, using the electroless copper-plated film as a power-supply layer, electrolytic copper plating was performed to form an electrolytic copper-plated film with a thickness of 10-30 μm on the surface of the resin insulation layer (see FIG. 5B).

The plated film (electroless copper-plated film and electrolytic copper-plated film) formed as above on the resin insulation layer was sanded by buff polishing to expose the surface of the resin insulation layer, and then was made flat (see FIG. 5C). For the polishing, a #600 buff sander was used.

In doing so, via conductor (14₁U₃) and inner-layer conductive circuit (14₂U) were formed. The line/space of inner-layer conductive circuit (14₂U) formed here was approximately 5 μm/5 μm.

Next, an interlayer film for build-up wiring (ABF series, made by Ajinomoto Fine Techno Co., Ltd.) was laminated on both surfaces of the support member, and thermoset at approximately 170° C. for 180 minutes to form resin insulation layers (uppermost resin insulation layers) (see FIG. 6A).

Then, using a carbon-dioxide gas laser, via-conductor openings were formed under conditions of wavelength 10.4 μm, beam diameter 4.0 mm, single mode, pulse width 8.0μ seconds and 1-3 shots (see FIG. 6B).

In the following, using an exima laser, recessed portions for conductive circuits were formed under conditions of wavelength 308 nm or 355 nm, while desmearing the bottoms of the above vias at the same time.

Next, by applying a palladium catalyst (made by Atotec) on the surface of the substrate, catalytic nuclei were adhered to the surface of the resin insulation layer including the opening portions and the recessed portions. Then, under the same conditions as above, an electroless copper-plated film with an approximate thickness of 0.3-1 μm was formed. Then, using the electroless copper-plated film as a power-supply layer, electrolytic copper plating was performed to form an electrolytic copper-plated layer with an approximate thickness of 20 μm on the surface of the resin insulation layer.

After that, the plated film (electroless copper-plated film and electrolytic copper-plated film) on the resin insulation layer was sanded by buff polishing using a #600 buff sander to expose the surface of the resin insulation layer, and was made flat (see FIG. 6C).

Accordingly, via conductors (16₁U₁, 16₁U₂) and inner-layer conductive circuits (16₂U₁, 16₂U₂) were formed (see FIG. 6C). The line/space (L/S) of inner-layer conductive circuits (16₂U₁, 16₂U₂) formed here was approximately 5 μm/5 μm.

After that, on uppermost resin insulation layer (24Uᵢ) and conductive circuits (16₂U₁, 16₂U₂), a commercially available solder-resist composition was applied to be approximately 30 μm thick, and was dried at 70° C. for 20 minutes and 70° C. for 30 minutes to form solder resist layer (30U). Then, a mask was placed on the solder resist layer (30U), and opening portions (51UO₁, 51UO₂) were formed by photolithography. Solder bumps (50U₁, 50U₂) were formed in those opening portions.

On the opposite side of support member (10), via conductor (16₁L₂) and inner-layer conductive circuits (16₂L₁, 16₂L₂, 16₂L₃)) were formed and solder resist (30L) was formed using the same process. A mask was placed on solder resist (30L), and opening portions (51LO₁, 51LO₂) were formed by photolithography. Solder bumps (50L₁, 50L₂) were formed in those opening portions.

### Example 2

Here, printed wiring board (100A) (see FIG. 8) described in the Second Embodiment was manufactured in the same way as in Example (1) except for the following two processes. On support member (BS), resin insulation layers were formed using the above-mentioned “ABF,” and conductive circuits were formed by a semi-additive method (see FIGS. 9A-9C). After that, resin insulation layers were formed in the same way as in Example (1), and via conductors and conductive circuits were formed using the same process as in (7) of Example (1) (see FIGS. 9D-10B)

### Comparative Example

A printed wiring board was manufactured in the same way as in Example (1), except that instead of the resin sheet used in (6) of Example (1), a film for interlayer insulation (ABF series, made by Ajinomoto Fine Techno Co., Ltd.) was used in which the inorganic filler contained in the resin has an average particle diameter of 1.0 μm and a maximum diameter of 5.0 μm, and is approximately 50 μm thick.

Evaluation

In the above Examples and a Comparative Example, the recessed-portion configurations for conductive circuits were observed using an electron microscope. The results were shown in FIGS. (19A-20B).

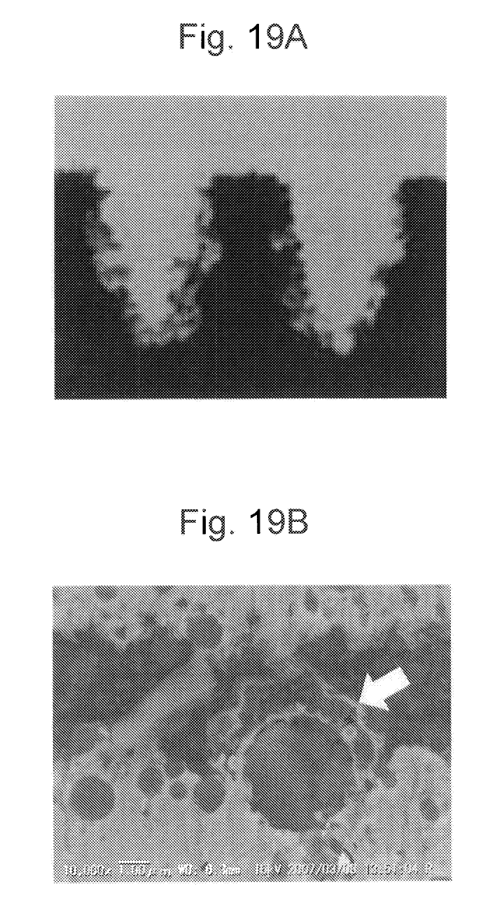

In a printed wiring board of the Comparative Example, as shown in FIG. 19A, it was found that the surface of the resin insulation layer in which the recessed portions were formed was substantially roughened. Then, as the white arrow shows in FIG. 19B, it was found that plating seeps into the area around inorganic particles (the space between the resin insulation layer and inorganic particles) that exist between lines of the conductive circuit, and also into the spots where inorganic particles fell off. Accordingly, in the Comparative Example, electrical features under the skin effect may be lowered and wiring insulation may also be decreased. In addition, in the Comparative Example, it was found that the resin insulation layers had undulating surfaces. Accordingly, interlayer insulation may be decreased.

Meanwhile, the printed wiring board manufactured in Example (1) was observed using a scanning electron microscope (SEM) to view its wiring configuration and so forth. The result is shown in FIG. 20A. As is obvious from FIG. 20A, substantial roughness caused by inorganic particles was not found. It indicates that in a printed wiring board manufactured according to a method of the present invention, it is possible to prevent a decrease in wiring insulation, which occurs in situations such as conductive substances seeping into gaps between fine particles such as inorganic particles and insulative substances such as resin, or conductive substances getting into holes formed when fine particles fall off.

Also, since the particle diameters of inorganic particles were smaller, the cross-sectional configuration of trench wiring became sharper. As a result, degradation of electrical characteristics (signal transmission) under the skin effect may be prevented. Also, it was found that the surfaces of the resin insulation layers were not undulating, but flat.

Furthermore, in the printed wiring board manufactured in Example (2), as shown in FIG. 20B, roughness was hardly observed on the surfaces of resin insulation layers where recessed portions are formed. As a result, it was found that the same effect as in Example (1) may be achieved.

[Potential Industrial Use]

As described above, a printed wiring board according to the present invention is useful for manufacturing a thinner type printed wiring board, and is suitable when used for making compact devices.

Furthermore, a method for manufacturing a printed wiring board according to the present invention is suitable for manufacturing a printed wiring board in which the flatness of resin insulation layers is secured and degradation of electrical characteristics (signal transmission) under the skin effect are prevented, while keeping productivity high.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
an insulative material;
a first conductive circuit formed on the insulative material;
a resin insulation layer comprising:
a first insulation layer formed on the insulative material and on the first conductive circuit and which insulates between lines of the first conductive circuit, the first insulation layer including inorganic particles having a first average diameter; and
a second insulation layer formed on the first insulation layer and including a recessed portion and an opening portion, the second insulation layer including inorganic particles having a second average diameter smaller than the first average diameter;
a second conductive circuit formed in the recessed portion; and
a via conductor formed in the opening portion and which connects the first conductive circuit to the second conductive circuit.

2. The printed wiring board according to claim 1, wherein a surface of the second conductive circuit formed in the recessed portion is set on substantially the same level as a surface of the resin insulation layer.

3. The printed wiring board according to claim 1, wherein a thickness of the first insulation layer is greater than a thickness of the first conductive circuit.

4. The printed wiring board according to claim 1, wherein a thickness of the second insulation layer is greater than a thickness of the second conductive circuit.

5. The printed wiring board according to claim 1, wherein an amount of second particles makes up 10-70 weight percent of a total weight of a resin that forms the second insulation layer.

6. The printed wiring board according to claim 1, wherein the first and second inorganic particles are coated with a surface reforming agent.

7. The printed wiring board according to claim 6, wherein the first and second inorganic particles are at least one or more kinds of compounds selected from among groups of inorganic oxides, carbides, inorganic nitrides, mineral salts and silicates.

8. A method for manufacturing a printed wiring board, comprising:
forming a first conductive circuit on a surface of an insulative material;
forming, on the insulative material and on the first conductive circuit, a resin insulation layer having a first insulation layer that includes first inorganic particles, and a second insulation layer that is formed on the first insulation layer and includes second inorganic particles whose average diameter is smaller than that of the first inorganic particles;
forming an opening portion for a via conductor that penetrates the resin insulation layer, and also forming a recessed portion for a second conductive circuit in the second insulation layer;
forming a second conductive circuit in the recessed portion; and
forming a via conductor in the opening portion that connects the first conductive circuit and the second conductive circuit.

9. The method for manufacturing a printed wiring board according to claim 8, wherein
the forming the recessed portion is such that a depth of the recessed portion is shallower than a thickness of the second insulation layer.

10. The method for manufacturing a printed wiring board according to claim 8, wherein
the forming the opening portion and the recessed portion is performed using a laser.

11. The method for manufacturing a printed wiring board according to claim 8, wherein
the forming the second conductive circuit is such that a surface of the resin insulation layer is set on substantially the same level as a surface of the second conductive circuit.

12. A printed wiring board, comprising:
an insulative material;
a first conductive circuit formed on the insulative material;
a resin insulation layer having a first insulation layer that is formed on the insulative material and on the first conductive circuit and insulates between lines of the first conductive circuit, a second insulation layer that is formed on the first insulation layer and has a recessed portion for a second conductive circuit, and an opening portion for a via conductor;
a second conductive circuit formed in the recessed portion; and
a via conductor that is formed in the opening portion and connects the first conductive circuit and the second conductive circuit, wherein
the first insulation layer includes first inorganic particles, and
the second insulation layer is essentially made only of resin.

13. A method for manufacturing a printed wiring board, comprising:
forming a first conductive circuit on a surface of an insulative material;
forming, on the insulative material and on the first conductive circuit, a resin insulation layer having a first insulation layer that includes first inorganic particles, and a second insulation layer that is formed on the first insulation layer and is essentially made only of resin;
forming an opening portion for a via conductor that penetrates the resin insulation layer, and also to a form a recessed portion for a second conductive circuit in the second insulation layer;
forming a second conductive circuit in the recessed portion; and
forming a via conductor in the opening portion that connects the first conductive circuit and the second conductive circuit.

14. A printed wiring board, comprising:
at least one resin insulation layer in which a first recessed portion is formed on a first-surface side and a second recessed portion is formed on a second-surface side;
a component-mounting pad formed in the first recessed portion;
a conductive circuit formed in the second recessed portion; and
a via conductor that carries out interlayer conductivity between the component-mounting pad and the conductive circuit, wherein the at least one resin insulation layer includes
a first insulation layer to insulate between the component-mounting pads,
a second insulation layer to insulate between lines of the conductive circuit, and
a via-conductor opening portion in which to form a via conductor, wherein
the first insulation layer includes first inorganic particles, and
the second insulation layer includes second inorganic particles whose particle diameters are smaller than those of the first inorganic particles.

15. A method for manufacturing a printed wiring board, comprising:
forming a component-mounting pad on a first surface of a support member;
forming, on the support member and on the component-mounting pad, a resin insulation layer having a first insulation layer that includes first inorganic particles, and a second insulation layer that is formed on the first insulation layer and includes second inorganic particles whose average diameter is smaller than that of the first inorganic particles;
forming an opening for a via conductor that penetrates the first insulation layer and the second insulation layer, and also forming a recessed portion for a second conductive circuit in the second insulation layer;
forming a second conductive circuit in the recessed portion; and
forming in the opening portion a via conductor to connect the first conductive layer and the second conductive circuit.

16. A printed wiring board, comprising:
at least one resin insulation layer in which a first recessed portion is formed on a first surface and a second recessed portion is formed on a second surface;
a component-mounting pad formed in the first recessed portion;
a conductive circuit formed in the second recessed portion; and
a via conductor that carries out interlayer conductivity between the component-mounting pad and the conductive circuit, wherein the at least one resin insulation layer includes
a first insulation layer to insulate between the component-mounting pads,
a second insulation layer to insulate between lines of the conductive circuit, and
a via-conductor opening portion in which to form a via conductor, wherein
the first insulation layer includes first inorganic particles, and
the second insulation layer is essentially made only of resin.

17. A method for manufacturing a printed wiring board, comprising:
forming a component-mounting pad on a first surface of a support member;
forming, on the support member and on the component-mounting pad, a resin insulation layer having a first insulation layer that includes first inorganic particles, and a second insulation layer that is formed on the first insulation layer and is essentially made only of resin;
forming an opening portion for a via conductor that penetrates the first insulation layer and the second insulation layer, and also forming a recessed portion for a conductive circuit in the second insulation layer;
forming a second conductive circuit in the recessed portion; and
forming a via conductor in the opening portion to connect the component-mounting pad and the conductive circuit.

18. The printed wiring board according to claim 12, wherein
the first inorganic particles are at least one or more kinds of compounds selected from among groups of inorganic oxides, carbides, inorganic nitrides, mineral salts and silicates.

19. The printed wiring board according to claim 14, wherein
the first and second inorganic particles are at least one or more kinds of compounds selected from among groups of inorganic oxides, carbides, inorganic nitrides, mineral salts and silicates.

20. The printed wiring board according to claim 16, wherein
the first inorganic particles are at least one or more kinds of compounds selected from among groups of inorganic oxides, carbides, inorganic nitrides, mineral salts and silicates.
